(19) United States
(12) Patent Application Publication
(10) Pub. No.: US 2026/0239642 A1
(43) Pub. Date: Aug. 13, 2026

(54) SEMICONDUCTOR DEVICE AND METHOD OF MANUFACTURING SEMICONDUCTOR DEVICE

(71) Applicant: Mitsubishi Electric Corporation, Tokyo (JP)

(72) Inventors: Yusuke MIYATA, Tokyo (JP); Kohei SAKO, Tokyo (JP); Koji TANAKA, Tokyo (JP); Naoyuki KAWABATA, Tokyo (JP); Kazuya KONISHI, Tokyo (JP)

(73) Assignee: Mitsubishi Electric Corporation, Tokyo (JP)

(21) Appl. No.: 19/417,012

(22) Filed: Dec. 11, 2025

(30) Foreign Application Priority Data
Feb. 13, 2025 (JP) 2025-021728

(51) Int. Cl. H10D 12/00; H10D 12/01; H10D 62/40; H10D 62/53; H10D 84/00

(52) U.S. Cl. CPC H10D 12/481; H10D 12/038; H10D 62/405; H10D 62/53; H10D 84/161

(57) ABSTRACT

A semiconductor device includes a bipolar-type semiconductor element that includes a semiconductor substrate having a drift layer of a first conductivity type formed therein, trenches formed in a first main surface of the semiconductor substrate, an electrode embedded in each trench via an insulation film, a mesa region located between the trenches in the semiconductor substrate, and a source layer of a first conductivity type or a contact layer of a second conductivity type formed in a surface layer of the mesa region on the first main surface side. Dislocations having an overall length greater than the width of the mesa region are formed in positions located on the side closer to a second main surface than the source layer or the contact layer in the mesa region.

### BACKGROUND

### Technical Field

The present disclosure relates to a semiconductor device and a method of manufacturing the semiconductor device.

### Description of the Background Art

For example, Japanese Patent Application Laid-Open No. 2019-129250 (Patent Document 1) discloses a technique for improving switching characteristics of IGBTs and diodes of a semiconductor device by providing a reduced carrier lifetime region having a high defect density in part of a drift region by the application of charged particles.

Like the technique disclosed in Patent Document 1, techniques for forming a reduced carrier lifetime region having a high defect density by the application of charged particles involve an increase in the number of steps of manufacturing a semiconductor device. This results in an increase in the manufacturing cost of the semiconductor device.

### SUMMARY

It is an object of the present disclosure to provide a reduced carrier lifetime region in a semiconductor device while suppressing an increase in the number of manufacturing steps.

A semiconductor device according to the present disclosure includes a bipolar-type semiconductor element. The bipolar-type semiconductor element includes a semiconductor substrate having a first main surface and a second main surface and having a drift layer of a first conductivity type formed therein, a plurality of trenches formed in the first main surface of the semiconductor substrate, an electrode embedded in each of the plurality of trenches via an insulation film, a mesa region that is a region located between the plurality of trenches in the semiconductor substrate, and a source layer of the first conductivity type or a contact layer of a second conductivity type formed in a surface layer of the mesa region on a side closer to the first main surface. The mesa region includes dislocations in positions located on a side closer to the second main surface than the source layer or the contact layer, the dislocations having an overall length greater than a width of the mesa region.

According to the present disclosure, it is possible to provide a reduced carrier lifetime region in the semiconductor device while suppressing an increase in the number of manufacturing steps.

These and other objects, features, aspects and advantages of the present disclosure will become more apparent from the following detailed description of the present disclosure when taken in conjunction with the accompanying drawings.

### BRIEF DESCRIPTION OF THE DRAWINGS

FIG. 1 is a diagram for describing an overview of a technique according to the present disclosure.

FIG. 2 is a diagram showing a three-dimensional image of a second dislocation.

FIG. 3 is a graph showing the relationship between the thickness of a gate trench insulation film and the depth of the second dislocation.

FIG. 4 is a plan view of a stripe-type semiconductor device chip.

FIG. 5 is a plan view of an island-type semiconductor device chip.

FIG. 6 is a plan view of an IGBT area.

FIG. 7 is a sectional view of the IGBT area.

FIG. 8 is another sectional view of the IGBT area.

FIG. 9 is a plan view of a diode area.

FIG. 10 is a sectional view of the diode area.

FIG. 11 is another sectional view of the diode area.

FIG. 12 is a sectional view of a boundary between the IGBT area and the diode area (section G-G).

FIG. 13 is a sectional view of a termination area.

FIG. 14 is another sectional view of the termination area.

FIG. 15 is a diagram for describing a method of manufacturing a semiconductor device.

FIG. 16 is a diagram for describing the method of manufacturing a semiconductor device.

FIG. 17 is a diagram for describing the method of manufacturing a semiconductor device.

FIG. 18 is a diagram for describing the method of manufacturing a semiconductor device.

FIG. 19 is a diagram for describing the method of manufacturing a semiconductor device.

FIG. 20 is a diagram for describing the method of manufacturing a semiconductor device.

FIG. 21 is a diagram for describing the method of manufacturing a semiconductor device.

FIG. 22 is a diagram for describing the method of manufacturing a semiconductor device.

FIG. 23 is a diagram for describing the method of manufacturing a semiconductor device.

FIG. 24 is a diagram for describing the method of manufacturing a semiconductor device.

FIG. 25 is a diagram for describing the method of manufacturing a semiconductor device.

FIG. 26 is a diagram for describing the method of manufacturing a semiconductor device.

FIG. 27 is a diagram showing an exemplary configuration of a semiconductor device according to Embodiment 1.

FIG. 28 is a diagram showing another exemplary configuration of the semiconductor device according to Embodiment 1.

FIG. 29 is a diagram showing another exemplary configuration of the semiconductor device according to Embodiment 1.

FIG. 30 is a diagram showing an exemplary configuration of a semiconductor device according to Embodiment 2.

FIG. 31 is a diagram showing another exemplary configuration of the semiconductor device according to Embodiment 2.

FIG. 32 is a diagram showing another exemplary configuration of the semiconductor device according to Embodiment 2.

FIG. 33 is a diagram showing an exemplary configuration of a semiconductor device according to Embodiment 3.

FIG. 34 is a diagram showing another exemplary configuration of the semiconductor device according to Embodiment 3.

FIG. 35 is a diagram showing another exemplary configuration of the semiconductor device according to Embodiment 3.

FIG. 36 is a diagram showing an exemplary configuration of a semiconductor device according to Embodiment 4.

FIG. 37 is a diagram showing another exemplary configuration of the semiconductor device according to Embodiment 4.

FIG. 38 is a diagram showing an exemplary configuration of a semiconductor device according to Embodiment 5.

FIG. 39 is a diagram showing an exemplary configuration of a semiconductor device according to Embodiment 6.

FIG. 40 is a diagram showing another exemplary configuration of the semiconductor device according to Embodiment 6.

FIG. 41 is a diagram showing another exemplary configuration of the semiconductor device according to Embodiment 6.

### DESCRIPTION OF THE PREFERRED EMBODIMENTS

### Forward

In the following description, n and p indicate conductivity types of semiconductors. According to the present disclosure, a first conductivity type is described as the n type and a second conductivity type as the p type, but the first conductivity type may be the p type, and the second conductivity type may be the n type. Moreover, n⁻ indicates a lower impurity concentration than n, and n⁺ indicates a higher impurity concentration than n. Similarly, p⁻ indicates a lower impurity concentration than p, and p⁺indicates a higher impurity concentration than p.

The degree of the impurity concentration in each region is assumed to be defined by a peak density. That is, a region with a high (or low) impurity concentration means a region with a high (or low) peak impurity density.

The following description is given regarding an insulated gate bipolar transistor (IGBT) or a reverse conducting IGBT (RC-IGBT) serving as a semiconductor element of a semiconductor device. The technique according to the present disclosure is however applicable to wide ranges of bipolar devices, and is applicable not only to IGBTs or RC-IGBTs but also to diodes, for example.

In the following description, silicon is described as a chief material (constituent element) of the semiconductor device. However, the chief material of the semiconductor device may, for example, be a different material such as silicon carbide, gallium nitride, gallium oxide, or diamond.

In the following description, first and second main surfaces are defined as the main surfaces of the semiconductor device. The first main surface may also be referred to as a “front side”. In the case where the semiconductor element is an IGBT, an emitter electrode is formed on the first main surface. In the case where the semiconductor element is an RC-IGBT, an anode electrode of a diode built in the RC-IGBT may also be formed on the first main surface, in addition to the emitter electrode. The second main surface may also be referred to as a “back side”. In the case where the semiconductor element is an IGBT, a collector electrode is formed on the second main surface. In the case where the semiconductor element is an RC-IGBT, a cathode electrode of the diode built in the RC-IGBT may also be formed on the second main surface, in addition to the collector electrode.

Like the semiconductor device, main surfaces of a semiconductor substrate that configures the semiconductor device are also defined as first and second main surfaces. That is, out of the two main surfaces of the semiconductor substrate, the first main surface of the semiconductor substrate is located on the first main surface side of the semiconductor device, and the second main surface of the semiconductor substrate is located on the second main surface side of the semiconductor device.

### Basic Principle of Technique According to Present Disclosure

Examples of power bipolar devices include IGBTs, diodes, and RC-IGBTs. The power bipolar devices often confront an issue of minority carrier emissions during turn-off.

A carrier lifetime is one physical property value contributing to carrier emissions. The carrier lifetime is the term referring to the duration of time in which free carriers disappear effectively, and carrier emissions are accelerated as the carrier lifetime becomes shorter. The power bipolar devices generally include a high-resistance drift layer and use a technique for reducing continuity losses by the conductivity modulation effect of accumulating electrons and holes in the drift layer. With this technique, however, it takes time to emit the once accumulated electrons and holes, and in the case of IGBTs, turn-off losses become an issue, and in the case of diodes, deterioration in recovery losses becomes an issue. To solve these issues, a technique for controlling the carrier lifetime is widely used.

A common method of controlling the carrier lifetime is the formation of point defects as described in Patent Document 1 given above. Point defects refer to crystal defects of atomic-level sizes such as silicon lattice vacancies, interstitial silicon, or a complex thereof in the case of a silicon semiconductor. Most point defects in the semiconductor have an energy level within a band gap and trap free carries, thus acting to reduce the carrier lifetime. Patent Document 1 describes a technique for reducing the carrier lifetime in a desired region of a semiconductor substrate by intentionally forming point detects in part by the application of charged particles.

However, the technique for reducing the carrier lifetime by the application of charged particles requires steps such as the step of forming a shielding material (mask) pattern for creation of a non-irradiated region, in addition to the step of applying charged particles. This brings up an issue of an increase in the number of manufacturing steps of the semiconductor device. Thus, there is demand for a technique for reducing the carrier lifetime in a desired position without increasing the number of manufacturing steps.

The present disclosure proposes a new bipolar device that makes use of dislocations. Dislocations refer to linear crystal defects caused by disturbances of atomic periodic structures, and they are clearly different from point defects developed by the application of charged particles. Dislocations may exist unintendedly in a semiconductor substrate and are thought to affect electrical characteristics or deterioration in the reliability of a semiconductor device. Until now, techniques for creating dislocations in arbitrary positions of a semiconductor substrate have never been present, and no devices have been proposed to actively use dislocations.

However, since dislocations may have an energy level within a band gap, dislocations are expected to have the effect of trapping free carriers, and are thought to have the property of reducing the carrier lifetime. The inventors of the technique according to the present disclosure have found a technique for forming dislocations different from known dislocations in arbitrary positions, thereby improving electrical characteristics without involving deterioration in reliability.

### Method of Observing Second Dislocation 201

A method of observing dislocations with the technique according to the present disclosure will be described. Here, known dislocations that are formed unintentionally are referred to as “first dislocations”, and dislocations that are newly formed with the technique according to the present disclosure are referred to as “second dislocations”.

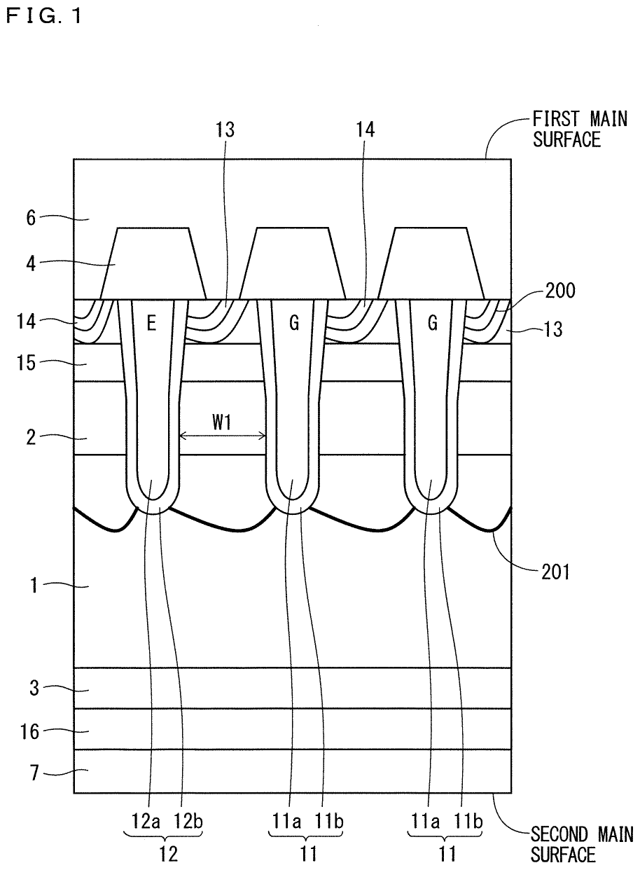

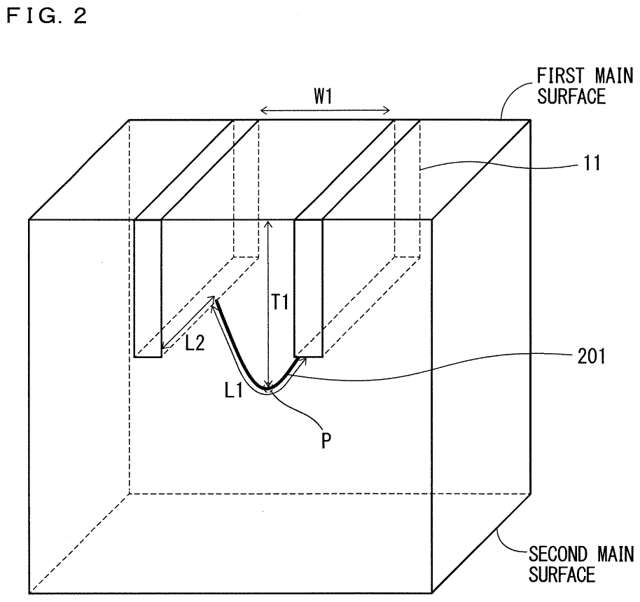

An overview of the technique according to the present disclosure will be described with reference to FIGS. 1 and 2. FIG. 1 is a sectional view of a semiconductor device, and FIG. 2 is a three-dimensional image of a second dislocation. FIG. 1 shows an example in which second dislocations 201 are formed in an n⁻-type drift layer 1 between active trench gates 11 of IGBTs. FIG. 2 three-dimensionally shows one second dislocation 201 between two active trench gates 11. Note that details of each element shown in FIG. 1 will be described later, and a description thereof will be omitted here.

Each second dislocation 201 has a structure that linearly extends three-dimensionally. When P is assumed to be the position of the second dislocation 201 that is closest to the second main surface of the semiconductor substrate, the distance from the first main surface of the semiconductor substrate to the position P is defined as a depth T1 of the second dislocation 201. An overall length L1 of the second dislocation 201 refers to the length of the linear dislocation extending three-dimensionally. The overall length L1 of the second dislocation 201 is longer than a mesa width W1 that is the width of a mesa-shaped semiconductor layer sandwiched between the trench gates. The overall length L1 of the second dislocation 201 may also include a component of a propagation distance L2 of the second dislocation 201 with respect to the direction of extension of the trench gates.

Since the second dislocations 201 shown in FIG. 1 extend in the depth direction on the plane of the drawing in FIG. 1 and have a three-dimensional linear structure as shown in FIG. 2, it is not possible to comprehend the second dislocations 201 in their entirety by observation using a general transmission electron microscope (TEM). Through detailed analysis of dislocations extending in three dimensional directions, the inventors of the technique according to the present disclosure have observed the unknown second dislocations 201 and have controlled positions where the second dislocations 201 are to be formed.

### Method of Arranging Second Dislocations

A mechanism for forming the second dislocations 201 will be described. The second dislocations 201 are formed by using first dislocations 200. The first dislocations 200 are known dislocations formed unintentionally and are generally created involuntarily when an n⁺-type source layer 13 or a p⁺-type contact layer 14 is formed in contact with the first main surface of the semiconductor substrate. As described above, “n⁺” and “p⁺” regions refer to regions with high impurity concentrations and are formed by ion implantation processing with a high implantation dose. The high implantation dose refers to a dose on the order of 10¹⁴ cm⁻² to 10¹⁶ cm⁻².

In general, in the case where impurities are doped by ion implantation processing, crystallinity of a semiconductor substrate becomes disturbed in a region (range) that has allowed the passage of implanted atoms. That is, a high-density defect region is formed in the region of the semiconductor substrate that has allowed the passage of implanted atoms. When heat treatment for activating a dopant is performed, the defect region is recovered or recrystallized. However, if the implantation dose is higher than or equal to a certain level, crystallinity is not recovered completely even by the heat treatment, and dislocations or point defects remain. The dislocations formed in this case are the first dislocations 200, and the first dislocations 200 can be observed easily with a general TEM.

The second dislocations 201 are formed by shifting the first dislocations 200 to an arbitrary depth by heat treatment of the first dislocations 200. The depth T1 of the second dislocations 201 relates to stresses in the semiconductor substrate. Various models are given as examples of the mechanism for forming dislocations, but a common principle is energy relaxation. It is known that crystals at high stresses are in a high energy state and energy is often released by the formation of dislocations (crystals enter a low energy state). That is, dislocations are easily formed in regions of high stress. Thus, controlling the stresses in the semiconductor substrate results in controlling the positions of the second dislocations 201.

One example of a stress control parameter is the thickness of a gate trench insulation film 11b. It is known experimentally that increasing the thickness of the gate trench insulation film 11b increases the stresses in the n⁻-type drift layer 1 including a mesa-shaped portion (this portion is hereinafter referred to as a “mesa region”). The stresses can also be evaluated quantitatively by convergent beam electron diffraction (CBED), but the magnitudes of the stresses can also be compared roughly by contrast between TEM images.

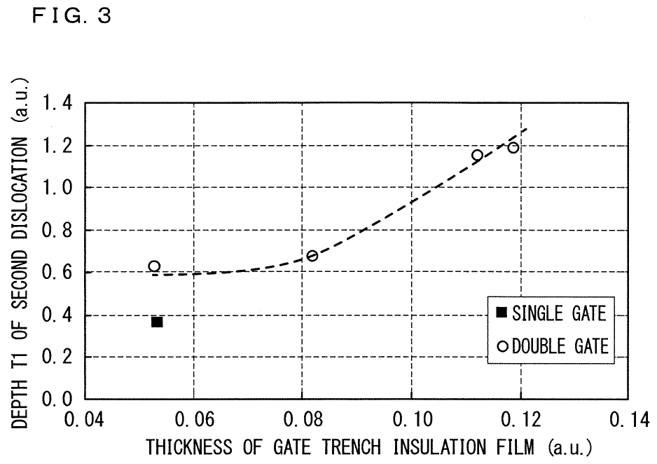

FIG. 3 shows the relationship between the thickness of the gate trench insulation film 11b and the depth T1 of the second dislocations 201 shown in FIG. 1. FIG. 3 shows the results of analysis of an actually prototyped semiconductor device. The depth T1 of the second dislocations 201 is standardized by the depth of the active trench gates 11, and the thickness of the gate trench insulation film 11b is standardized by the pitches of the active trench gates 11.

Increasing the thickness of the gate trench insulation film 11b increases the stresses in the n⁻-type drift layer 1 including the mesa region. To release the stresses (or strain energy), the first dislocations 200 are shifted to the n⁻-type drift layer 1 including the mesa region, thereby forming the second dislocations 201.

Here, as a model of the second dislocations 201, the second dislocations 201 formed by shifting the first dislocations 200 are described, but there is the possibility that the second dislocations 201 may be created from a different starting point. Detailed discussions thereof are however omitted here because a highly sophisticated analysis is necessary to accurately understand the source of the second dislocations 201, and even if the source of the dislocations is incorrect, little influence is exerted on the advantageous effects achieved by the technique according to the present disclosure.

Here, description is given regarding a difference in manufacturing steps between a conventional method of reducing the lifetime by the application of charged particles (e.g., Patent Document 1) and the technique according to the present disclosure. As described previously, the conventional method of reducing the lifetime involves an increase in the number of steps of manufacturing the semiconductor device because the conventional method requires steps such as the step of applying charged particles and the step of forming a shielding material (mask) pattern for creating a non-irradiated region. On the other hand, with the technique according to the present disclosure, positions where the second dislocations 201 are to be arranged (positions where stresses are controlled) can be controlled by controlling the design parameter, i.e., the thickness of the insulation film (gate trench insulation film 11b). To form the second dislocations 201, heat treatment of the first dislocations 200 is necessary, but this heat treatment does not necessarily have to be a step that is added in order to shift the dislocations, and for example, the first dislocations 200 may be heat-treated simultaneously by the heat treatment performed for activating the n⁺-type source layer 13 or the p⁺-type contact layer 14. Therefore, the technique according to the present disclosure is capable of reducing the lifetime in a desired position without increasing the number of manufacturing steps.

In the technique according to the present disclosure, the stress control parameter is not limited to the thickness of the gate trench insulation film 11b. For example, other parameters such as the pitch, shape, or depth of the trenches in the gate trench insulation film 11b or design parameters of the electrode embedded in the trenches (a gate trench electrode 11a) are also thought to be used as control parameters for controlling the positions where the second dislocations 201 are to be arranged (positions where stresses are controlled). The insulation film whose thickness is used as the stress control parameter is not limited to the gate trench insulation film 11b, and the thicknesses of other insulation films such as a dummy trench insulation film 12b, a diode trench insulation film 21b, a terminal dummy trench insulation film 35b, an upper gate trench insulation film 36b, and a lower gate trench insulation film 36d, which will be described later, may also be used as the stress control parameter. By controlling these design parameters with respect to the region in which the second dislocations 201 are desired to be arranged, the second dislocations 201 can be arranged in arbitrary positions, and no special step is required to form the second dislocations 201.

### Advantageous Effects Common to Each Embodiment

With the technique according to the present disclosure, electrical characteristics of the semiconductor device are improved by using dislocations so as to locally reduce the carrier lifetime. Here, an example of using dislocations in a power control semiconductor device (power semiconductor) will be introduced.

A reduced carrier lifetime generally brings about the effect of accelerating trapping of minority carriers. In a bipolar device for power control, a region with a high impurity concentration is provided in the first and second main surfaces, and a region with a low impurity concentration, called a drift layer, is configured between the first and second main surfaces. The drift layer has a high resistance because of the low impurity concentration, but it is possible to lower the resistance during continuity and thereby to reduce continuity losses by the conductivity modulation effect specific for the bipolar device. In the case of a diode, the diode transitions from a conducting (ON) state to a non-conducting (OFF) state by the application of a reverse voltage, and power losses caused during this period are called recovery losses. In the case of an IGBT, the IGBT is caused to transition between ON and OFF states with arbitrary timing by a gate potential. Power losses caused during the period of transition from the ON state to the OFF state are called turn-off losses, and conversely power losses caused during the period of transition from the OFF state to the ON state are called turn-on losses. A total of recovery losses, turn-off losses, and turn-on losses is called switching losses. The conductivity modulation effect is effective in reducing power losses during the ON-state, but brings up an issue of increasing switching losses. Switching losses have a trade-off relationship with continuity losses and are controlled by the impurity concentration in the collector layer or the impurity concentration in the cathode region.

There is a technique for improving the trade-off between switching losses and continuity losses by reducing the carrier lifetime. Turn-off losses and recovery losses, which are main elements of switching losses, are caused by minority carrier emissions. That is, switching losses can be reduced by efficient minority carrier emissions. Reducing the carrier lifetime is one technique for efficiently emitting minority carriers. Efficient minority carrier emissions are also expected to bring about the effect of increasing the interrupting capacity.

In the case where the carrier lifetime is reduced in an arbitrary region of the semiconductor device, an important design item is to consider which electrical characteristics should be taken into account. Meanwhile, in the case where defects are introduced into the semiconductor device irrespective of the dislocations, concern is given about an increase in leakage current during turn-off, a change in threshold voltage, and deterioration in gate reliability. Moreover, in the case of a bipolar device, a reduced carrier lifetime is expected to reduce switching losses and increase the interrupting capacity, but in contrast, it reduces the conductivity modulation effect and increases continuity losses. The designers need to assess the trade-off relationship therebetween and to arrange dislocations in optimum positions.

The second dislocations 201 are characterized by the overall length L1 greater than the mesa width W1. The overall length L1 of the second dislocations 201 refers to the propagation distance in a three-dimensional space and also includes a component in the depth direction on the plane of the drawing in FIG. 2. By arranging the second dislocations 201 of the great overall length L1, it is possible to enlarge a region in which the carrier lifetime is reduced. The second dislocations 201 may be curved, or may have a convex shape toward the second main surface. By curving the second dislocations 201, it is possible to increase the propagation distance of the second dislocations 201 and to enlarge a region in which the carrier lifetime is reduced. In the case where the second dislocations 201 are formed in order to control stresses in the vicinity of the active trench gates 11, the second dislocations 201 are formed in positions that are in contact with the active trench gates 11 as shown in FIGS. 1 and 2. In the case where the carrier lifetime is reduced in the direction toward the second main surface of the n⁻-type drift layer 1, a higher effect is achieved by shaping the second dislocations 201 in a convex shape toward the second main surface.

### Matters Common to All Embodiments

A description here is given regarding matters common to all embodiments described below.

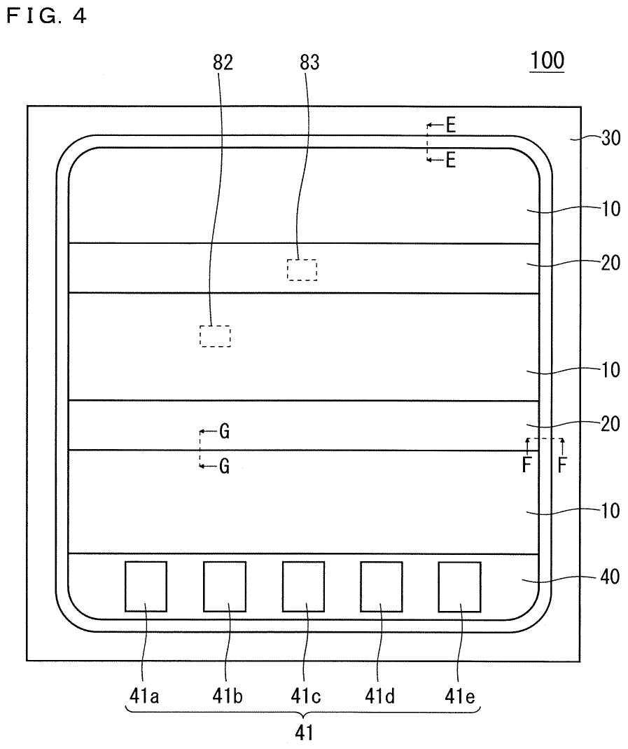

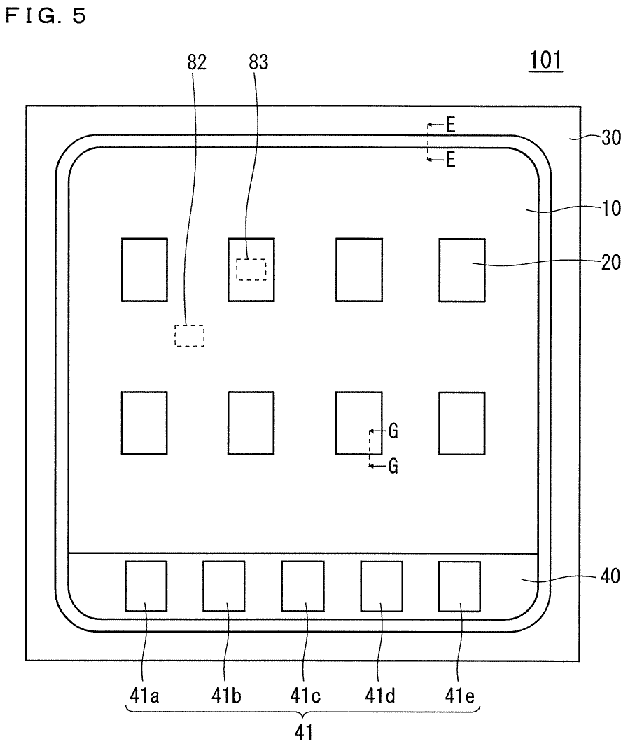

FIG. 4 is a plan view showing a semiconductor device that is an RC-IGBT. FIG. 5 is a plan view showing a semiconductor device that is an RC-IGBT having another configuration. A semiconductor device 100 shown in FIG. 4 includes IGBT areas 10 and diode areas 20 arranged in stripes, and may be simply referred to as “of a stripe type”. A semiconductor device 101 shown in FIG. 5 includes a plurality of diode areas 20 arranged in longitudinal and lateral directions and an IGBT area 10 provided around the diode areas 20, and may be simply referred to as “of an island type”.

### (1) Overall Planar Structure of Stripe Type

In FIG. 4, the semiconductor device 100 includes the IGBT areas 10 and the diode areas 20. The IGBT areas 10 and the diode areas 20 extend from one end side of the semiconductor device 100 to the other end side thereof and are alternately arranged in stripes in a direction orthogonal to the direction of extension of the IGBT areas 10 and the diode areas 20. FIG. 4 shows three IGBT areas 10 and two diode areas 20 and shows a configuration in which the diode areas 20 are sandwiched by the IGBT areas 10, but the numbers of IGBT areas 10 and the number of diode areas 20 are not limited to the above example. The number of IGBT areas 10 may be greater than or equal to three or may be less than or equal to three, and the number of diode areas 20 may be greater than or equal to two or may be less than or equal two. A configuration is also possible in which the IGBT areas 10 and the diode areas 20 in FIG. 4 may be replaced in position, or a configuration is also possible in which all of the IGBT areas 10 are sandwiched by the diode areas 20. Another configuration is also possible in which one IGBT area 10 and one diode area 20 are provided adjacent to each other.

As shown in FIG. 4, a pad area 40 is provided adjacent to the underside of the IGBT area 10 on the plane of the drawing. The pad area 40 is an area in which control pads 41 are provided in order to control the semiconductor device 100. The IGBT areas 10 and the diode areas 20 are collectively referred to as a “cell area”. Around an area that combines the cell area and the pad area 40, a termination area 30 is provided in order to retain the withstand voltage of the semiconductor device 100. The termination area 30 may have a known withstand-voltage retaining structure that is selected as appropriate. The withstand-voltage retaining structure may be configured to include, for example, a field limiting ring (FLR) or a variation of lateral doping (VLD) on the first main surface side, i.e., on the front side of the semiconductor device 100, the FLR surrounding the area that combines the cell area and the pad area 40 with a p-type terminal well layer of a p-type semiconductor, the VLD surrounding the area that combines the cell area and the pad area 40 with a p-type terminal well layer having a concentration gradient. The number of p-type terminal well layers of a ring shape used in the FLR and the concentration distribution used in the VLD may be selected as appropriate according to the withstand-voltage design of the semiconductor device 100. Alternatively, a p-type terminal well layer may be provided almost across the pad area 40, or IGBT cells or diode cells may be provided in the pad area 40.

The control pads 41 may include, for example, a current sensing pad 41a, a Kelvin emitter pad 41b, a gate pad 41c, and temperature sensing diode pads 41d and 41e. The current sensing pad 41a is a control pad for sensing current flowing through the cell area of the semiconductor device 100, and is also a control pad that is electrically connected to some of the IGBT cells or the diode cells in the cell area so as to pass a current that is a fraction of several or several tens of thousands of the current flowing through the entire cell area during current flow in the cell area of the semiconductor device 100.

The Kelvin emitter pad 41b and the gate pad 41c are control pads to which a gate driving voltage is applied in order to control turn-on and turn-off of the semiconductor device 100. The Kelvin emitter pad 41b is electrically connected to a p-type base layer and an n⁺-type emitter layer of the IGBT cells, and the gate pad 41c is electrically connected to gate trench electrodes of the IGBT cells. The Kelvin emitter pad 41b and the p-type base layer may be electrically connected to each other via a p⁺-type contact layer. The temperature sensing diode pads 41d and 41e are control pads electrically connected to anodes and cathodes of temperature sending diodes provided in the semiconductor device 100. The temperature of the semiconductor device 100 is measured by measuring a voltage between anodes and cathodes (not shown) of the temperature sensing diodes provided in the cell area.

### (2) Overall Planar Structure of Island Type

In FIG. 5, one semiconductor device 101 includes an IGBT area 10 and a plurality of diode areas 20. The diode areas 20 are arranged in longitudinal and lateral directions within the semiconductor device and surrounded by the IGBT area 10. That is, the diode areas 20 are provided in islands within the IGBT area 10. FIG. 5 shows a configuration in which the diode areas 20 are provided in a matrix with two rows in the up-down direction and four columns in the right-left direction on the plane of the drawing, but the number of diodes areas 20 and the arrangement of the diode areas 20 are not limited to this example. The semiconductor device 101 may have a configuration in which one or a plurality of diode areas 20 are scattered within the IGBT area 10, and each diode area 20 is surrounded by the IGBT area 10.

As shown in FIG. 5, a pad area 40 is provided adjacent to the underside of the IGBT area 10 on the plane of the drawing. The pad area 40 is an area in which control pads 41 are provided in order to control the semiconductor device 101. The IGBT area 10 and the diode areas 20 are collectively referred to as a “cell area”. Around an area that combines the cell area and the pad area 40, a termination area 30 is provided in order to retain the withstand voltage of the semiconductor device 101. The termination area 30 may have a known withstand-voltage retaining structure that is selected as appropriate. The withstand-voltage retaining structure may be configured to include, for example, a FLR or a VLD on the first main surface side, i.e., on the front side of the semiconductor device 101, the FLR surrounding the area that combines the cell area and the pad area 40 with a p-type terminal well layer of a p-type semiconductor, the VLD surrounding the area that combines the cell area and the pad area 40 with a p-type terminal well layer having a concentration gradient. The number of p-type terminal well layers of a ring shape used in the FLR and the concentration distribution used in the VLD may be selected as appropriate according to the withstand-voltage design of the semiconductor device 101. Alternatively, a p-type terminal well layer may be provided almost across the pad area 40, or IGBT cells or diode cells may be provided in the pad area 40.

The control pads 41 may include, for example, a current sensing pad 41a, a Kelvin emitter pad 41b, a gate pad 41c, and temperature sensing diode pads 41d and 41e. The current sensing pad 41a is a control pad for sensing current flowing through the cell area of the semiconductor device 101, and is also a control pad that is electrically connected to some of the IGBT or diode cells in the cell area so as to allow the passage of current that is a fraction of several or several tens of thousands of current flowing through the entire cell area during current flow in the cell area of the semiconductor device 101.

The Kelvin emitter pad 41b and the gate pad 41c are control pads to which a gate driving voltage is applied in order to control turn-on and turn-off of the semiconductor device 101. The Kelvin emitter pad 41b is electrically connected to a p-type base layer and an n⁺-type source layer of the IGBT cells, and the gate pad 41c is electrically connected to gate trench electrodes of the IGBT cells. The Kelvin emitter pad 41b and the p-type base layer may be electrically connected to each other via a p⁺-type contact layer. The temperature sensing diode pads 41d and 41e are control pads electrically connected to anodes and cathodes of temperature sensing diodes provided in the semiconductor device 101. The temperature of the semiconductor device 101 is measured by measuring a voltage between the anodes and the cathodes (not shown) provided in the cell area.

### (3) Exemplary Structure of IGBT Area 10

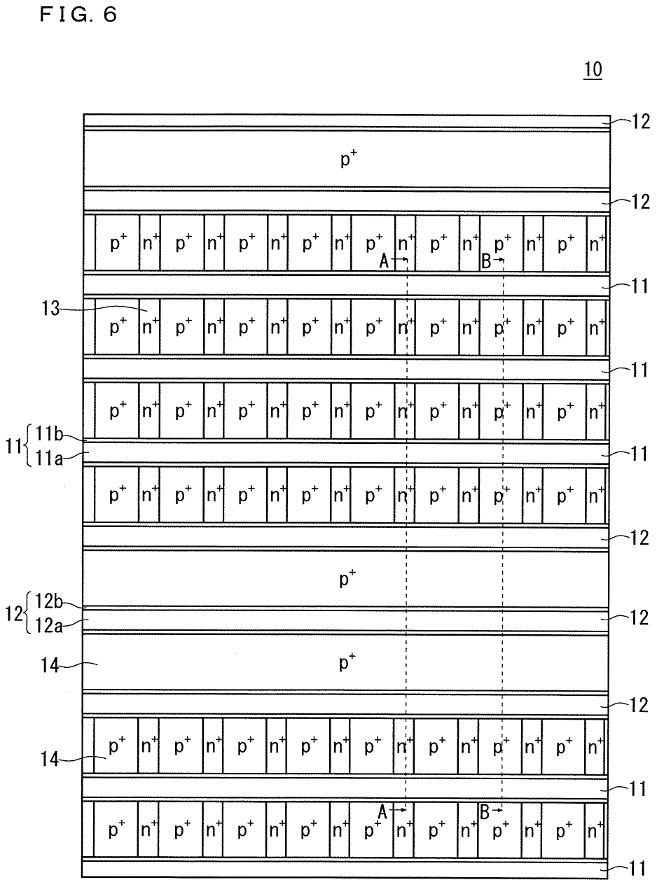

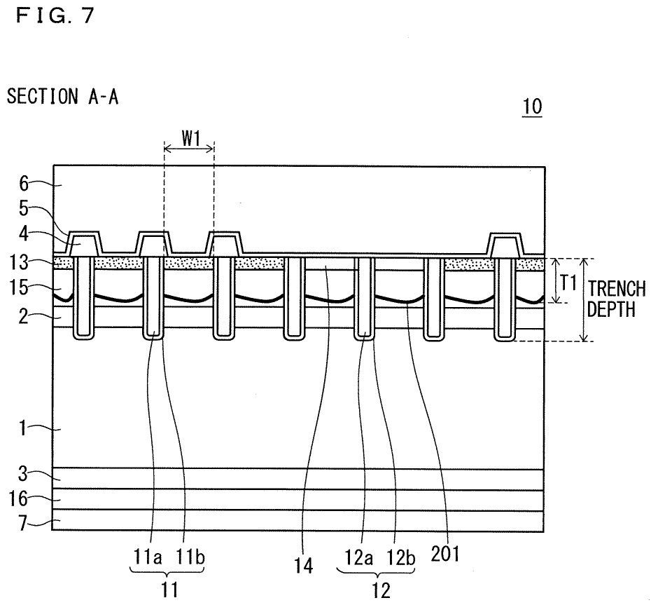

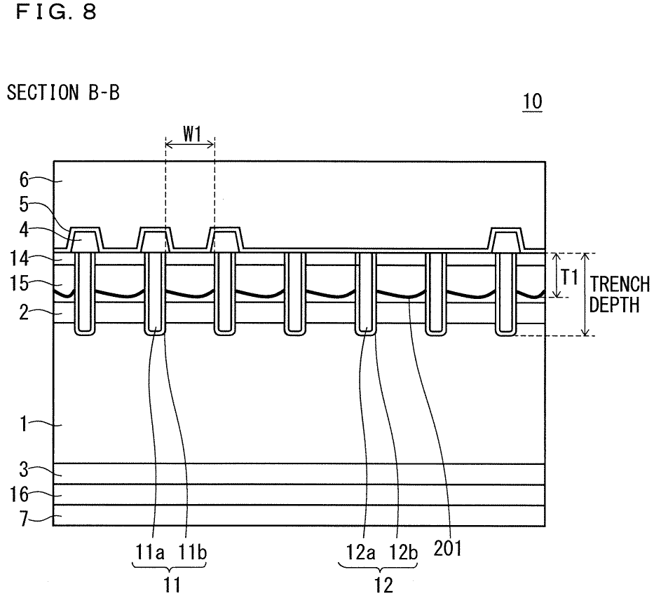

FIG. 6 is a partial enlarged plan view showing a configuration of an IGBT area of a semiconductor device that is an RC-IGBT. FIGS. 7 and 8 are sectional views showing the configuration of the IGBT area of the semiconductor device that is an RC-IGBT. FIG. 6 is an enlarged view of an area enclosed by a broken line 82 in the semiconductor device 100 shown in FIG. 4 or the semiconductor device 101 shown in FIG. 5. FIG. 7 is a sectional view of the semiconductor device 100 or 101 taken along a broken line A-A shown in FIG. 6, and FIG. 8 is a sectional view of the semiconductor device 100 or 101 taken along a broken line B-B shown in FIG. 6.

As shown in FIG. 6, the IGBT area 10 includes active trench gates 11 and dummy trench gates 12 arranged in stripes. In the semiconductor device 100, the active trench gates 11 and the dummy trench gates 12 extend in the longitudinal direction of the IGBT area 10, and the longitudinal direction of the IGBT area 10 corresponds to the longitudinal direction of the active trench gates 11 and the dummy trench gates 12. Meanwhile, in the semiconductor device 101, there is no particular need to distinguish between the long and short sides of the IGBT area 10, but the right-left direction on the plane of the drawing may be defined as the longitudinal direction of the active trench gates 11 and the dummy trench gates 12, or the up-down direction on the plane of the drawing may be defined as the longitudinal direction of the active trench gates 11 and the dummy trench gates 12.

Each active trench gates 11 is configured by providing a gate trench electrode 11a via a gate trench insulation film 11b within a trench formed in the semiconductor substrate. Each dummy trench gate 12 is configured by providing a dummy trench electrode 12a via a dummy trench insulation film 12b in a trench formed in the semiconductor substrate. The gate trench electrodes 11a of the active trench gates 11 are electrically connected to the gate pad 41c. The dummy trench electrodes 12a of the dummy trench gates 12 are electrically connected to an emitter electrode that is provided on the first main surface of the semiconductor device 100 or 101.

The n⁺-type source layer 13 is provided in contact with the gate trench insulation films 11b on both sides in the width direction of the active trench gates 11. The n⁺-type source layer 13 is a semiconductor layer that contains, for example, arsenic or phosphorus as an n-type impurity, and the concentration of the n-type impurity is in the range of 1.0E+17/cm³ to 1.0E+20/cm³. The n⁺-type source layer 13 and the p⁺-type contact layer 14 are alternated in the direction of extension of the active trench gates 11. The p⁺-type contact layer 14 is also provided between each pair of adjacent dummy trench gates 12. The p⁺-type contact layer 14 is a semiconductor layer that contains, for example, boron or aluminum as a p-type impurity, and the concentration of the p-type impurity is in the range of 1.0E+15/cm³ to 1.0E+20/cm³.

In FIG. 6, only the p⁺-type contact layer 14 is arranged between the dummy trench gates 12, but the n⁺-type source layer 13 may be arranged between the dummy trench gates 12.

As shown in FIG. 6, the IGBT area 10 of the semiconductor device 100 or 101 has a configuration in which three active trench gates 11 are arranged side by side, three dummy trench gates 12 are arranged side by side adjacent to these active trench gates 11, three active trench gates 11 are arranged side by side adjacent to these dummy trench gates 12, and three dummy trench gates 12 are arranged side by side adjacent to these active gate trenches 11. In this way, the IGBT area 10 has a configuration in which a set of active trench gates 11 and a set of dummy trench gates 12 are alternately arranged side by side. In FIG. 6, three active trench gates 11 are included in one set of active trench gates 11, but the number of active trench gates 11 included in each set may be one or more. The number of dummy trench gates 12 included in one set of dummy trench gates 12 may be one or more, and the number of dummy trench gates 12 may be zero. That is, all of the trenches provided in the IGBT area 10 may be the active trench gates 11.

FIG. 7 is a sectional view of the semiconductor device 100 or 101 taken along the broken line A-A in FIG. 6, and is also a sectional view of the IGBT area 10. The semiconductor device 100 or 101 includes the n⁻-type drift layer 1 configured by a semiconductor substrate. The n⁻-type drift layer 1 is a semiconductor layer that contains, for example, arsenic or phosphorus as an n-type impurity, and the concentration of the n-type impurity is in the range of 1.0E+12/cm³ to 1.0E+15/cm³. In FIG. 7, the semiconductor substrate ranges from the n⁺-type source layer 13 or the p⁺-type contact layer 14 to a p-type collector layer 16. In FIG. 7, the upper ends of the n⁺-type source layer 13 and the p⁺-type contact layer 14 on the plane of the drawing are referred to as the first main surface of the semiconductor substrate, and the lower end of the p-type collector layer 16 on the plane of the drawing is referred to as the second main surface of the semiconductor substrate. The first main surface of the semiconductor substrate corresponds to the main surface of the semiconductor device 100 or 101 on the front side, and the second main surface of the semiconductor substrate corresponds to the main surface of the semiconductor device 100 or 101 on the back side. The semiconductor device 100 or 101 includes the n⁻-type drift layer 1 between the first main surface and the second main surface facing the first main surface in the IGBT area 10 that is the cell area.

Depending on the manufacturing method, various impurities are mixed into the semiconductor substrate. Examples of the impurities include oxygen, carbon, boron, and nitrogen. These impurities are known to affect electrical characteristics or diffusion of impurity elements.

As shown in FIG. 7, in the IGBT area 10, an n-type carrier storage layer 2 having a higher n-type impurity concentration than the n⁻-type drift layer 1 is provided on the first main surface side of the n⁻-type drift layer 1. The n-type carrier storage layer 2 is a semiconductor layer that contains, for example, arsenic or phosphorus as an n-type impurity, and the concentration of the n-type impurity is in the range of 1.0E+13/cm³ to 1.0E+17/cm³. Note that the semiconductor device 100 or 101 may have a configuration in which the n⁻-type drift layer 1 is further provided in the region of the n-type carrier storage layer 2 shown in FIG. 7 without forming the n-type carrier storage layer 2. The presence of the n-type carrier storage layer 2 reduces continuity losses during current flow in the IGBT area 10. The n-type carrier storage layer 2 and the n⁻-type drift layer 1 may be collectively referred to as a “drift layer”.

The n-type carrier storage layer 2 is formed by implanting n-type impurity ions into the semiconductor substrate that configures the n⁻-type drift layer 1 and then diffusing the implanted n-type impurity within the semiconductor substrate, i.e., the n⁻-type drift layer 1, by annealing.

A p-type base layer 15 is provided on the first main surface side of the n-type carrier storage layer 2. The p-type base layer 15 is a semiconductor layer that contains, for example, boron or aluminum as a p-type impurity, and the concentration of the p-type impurity is in the range of 1.0E+12/cm³ to 1.0E+19/cm³. The p-type base layer 15 is in contact with the gate trench insulation films 11b of the active trench gates 11. On the first main surface side of the p-type base layer 15, the n⁺-type source layer 13 is provided in contact with the gate trench insulation films 11b of the active trench gates 11, and the p⁺-type contact layer 14 is provided in the remaining region. The n⁺-type source layer 13 and the p⁺-type contact layer 14 configure the first main surface of the semiconductor substrate. Note that the p⁺-type contact layer 14 may be a region having a higher p-type impurity concentration than the p-type base layer 15. In the case where there is the need to distinguish between the p⁺-type contact layer 14 and the p-type base layer 15, the p⁺-type contact layer 14 and the p-type base layer 15 may be referred to individually, or they may be collectively referred to as a p-type base layer

The semiconductor device 100 or 101 further includes an n-type buffer layer 3 having a higher n-type impurity concentration than the n⁻-type drift layer 1 on the second main surface side of the n⁻-type drift layer 1. The n-type buffer layer 3 is provided in order to suppress punch-through of a depletion layer extending from the p-type base layer 15 toward the second main surface during the OFF state of the semiconductor device 100 or 101. For example, the n-type buffer layer 3 may be formed by implanting phosphorus (P) or proton (H+), or may be formed by implanting both phosphorus (P) and proton (H+). The n-type buffer layer 3 has an n-type impurity concentration of 1.0E+12/cm³ to 1.0E+18/cm³.

Note that the semiconductor device 100 or 101 may have a configuration in which the n⁻-type drift layer 1 is further provided in the region of the n-type buffer layer 3 shown in FIG. 7 without forming the n-type buffer layer 3. The n-type buffer layer 3 and the n⁻-type drift layer 1 may be collectively referred to as a drift layer.

The semiconductor device 100 or 101 includes the p-type collector layer 16 provided on the second main surface side of the n-type buffer layer 3. That is, the p-type collector layer 16 is provided between the n⁻type drift layer 1 and the second main surface. The p-type collector layer 16 is a semiconductor layer that contains, for example, boron or aluminum as a p-type impurity, and the concentration of the p-type impurity is in the range of 1.0E+16/cm³ to 1.0E+20/cm³. The p-type collector layer 16 configures the second main surface of the semiconductor substrate. The p-type collector layer 16 is provided not only in the IGBT area 10 but also in the termination area 30, and the portion of the p-type collector layer 16 that is provided in the termination area 30 configures a p-type terminal collector layer 16a. Moreover, part of the p-type collector layer 16 may extend off the IGBT area 10 toward the diode area 20.

As shown in FIG. 7, the semiconductor device 100 or 101 has trenches extending from the first main surface of the semiconductor substrate through the p-type base layer 15 to the n⁻-type drift layer 1. The active trench gates 11 are configured by providing the gate trench electrodes 11a in the trenches via the gate trench insulation films 11b. The gate trench electrodes 11a face the n⁻type drift layer 1 via the gate trench insulation films 11b. The dummy trench electrodes 12a are configured by providing the dummy trench electrodes 12a in the trenches via the dummy trench insulation films 12b. The dummy trench electrodes 12a face the n⁻-type drift layer 1 via the dummy trench insulation film s12b. The gate trench insulation films 11b of the active trench gates 11 are in contact with the p-type base layer 15 and the n⁺-type source layer 13. When a gate driving voltage is applied to the gate trench electrodes 11a, a channel is formed in the p-type base layer 15 that is in contact with the gate trench insulation films 11b of the active trench gates 11.

Although not shown, the active trench gates 11 may include two gate trench electrodes 11a having different potentials in order to control gate capacitance. That is, one gate trench electrode 11a may be divided into upper and lower sections that are electrically isolated from each other by an insulation film. Such a gate structure is called a double gate structure.

As shown in FIG. 7, an interlayer insulation film 4 is provided on the gate trench electrodes 11a of the active trench gates 11. A barrier metal 5 is formed on the interlayer insulation film 4 and on a region of the first main surface of the semiconductor substrate on which the interlayer insulation film 4 is not formed. The barrier metal 5 may, for example, be a conductor that contains titanium (Ti), examples of which includes titanium nitride, and TiSi obtained by alloying titanium with silicon (Si). As shown in FIG. 7, the barrier metal 5 is in ohmic contact with and electrically connected to the n⁺-type source layer 13, the p⁺-type contact layer 14, and the dummy trench electrodes 12a. An emitter electrode 6 is provided on the barrier metal 5. The emitter electrode 6 may be formed of, for example, an aluminum alloy such as an aluminum silicon alloy (Al-Si alloy) or a material configured primarily of copper, and may have an electrode configuration including a plurality of layers of metal film so that a plating film is formed on the electrode by electroplating or electroless plating. The plating film formed by electroplating or electroless plating may, for example, be a nickel (Ni) plating film. In the case where the emitter electrode 6 has fine regions such as interstices with the adjacent interlayer insulation film 4 in which favorable embedding is not possible, tungsten having a more favorable embedding property than the emitter electrode 6 may be arranged in those fine regions, and the emitter electrode 6 may be provided on the tungsten. Alternatively, the emitter electrode 6 may be provided on the n⁺-type source layer 13, the p⁺-type contact layer 14, and the dummy trench electrodes 12a without the provision of the barrier metal 5. As another alternative, the barrier metal 5 may be provided on only the n-type semiconductor layers such as the n⁺-type source layer 13. The barrier metal 5 and the emitter electrode 6 may be collectively referred to as an emitter electrode. In the illustration of FIG. 7, the interlayer insulation film 4 is not formed on the dummy trench electrodes 12a of the dummy trench gates 12, but the interlayer insulation film 4 may also be formed on the dummy trench electrodes 12a of the dummy trench gates 12. In the case where the interlayer insulation film 4 is formed on the dummy trench electrodes 12a of the dummy trench gates 12, the emitter electrode 6 and the dummy trench electrodes 12a may be electrically connected to each other in a different section.

A collector electrode 7 is provided on the second main surface side of the p-type collector layer 16. Like the emitter electrode 6, the collector electrode 7 may be configured by an aluminum alloy, a material composed primarily of copper, or a combination thereof and a plating film. The collector electrode 7 may be different in configuration from the emitter electrode 6. The collector electrode 7 is in ohmic contact with and electrically connected to the p-type collector layer 16.

FIG. 8 is a sectional view of the semiconductor device 100 or 101 taken along the broken line B-B in FIG. 6, and is also a sectional view of the IGBT area 10. This sectional view is different from the sectional view taken along the broken line A-A shown in FIG. 7 in that the n⁺-type source layer 13 provided in contact with the active trench gates 11 on the first main surface side of the semiconductor substrate is not found in the section taken along the broken line B-B in FIG. 8. That is, as shown in FIG. 7, the n⁺-type source layer 13 is selectively provided on the first main surface side of the p-type base layer. The-p type base layer as used herein refers to the p-type base layer that combines the p-type base layer 15 and the p⁺-type contact layer 14.

As shown in FIGS. 7 and 8, the second dislocations 201 are arranged in positions of the semiconductor substrate on the side closer to the second main surface than the n⁺-type source layer 13 and the p⁺-type contact layer 14. The known first dislocations 200 also exist inside the n⁺-type source layer 13 and the p+-type contact layer 14, but the illustration thereof is omitted here. The second dislocations 201 are crystal defects that expand three-dimensionally and extend also in the depth direction on the plane of the drawing. The overall length L1 of the second dislocations 201 is greater than the mesa width W1. The overall length L1 is not the length of the curve in plan view, and refers to the length of a curve in stereoscopic vision. It is not easy to measure the length of the curve in stereoscopic vision, but in the case where the curve extends also in the depth direction on the plane of the drawing in FIGS. 7 and 8, in general, it can be safely said that the following inequality is satisfied: “linear dimensions in plan view”<“curve length in plan view”<“curve length in stereoscopic vision”. Here, if “curve length in plan view”=“curve length in stereoscopic vision” is satisfied, this indicates that the dislocations do not extend in the depth direction on the plane of the drawing. If “linear dimensions in plan view”=“curve length in plan view” is satisfied, this indicates that the dislocations have a linear shape and do not extend in the depth direction.

The second dislocations 201 are selectively arranged in positions that are three-dimensionally different from the positions of the first dislocations 200. The first dislocations 200 are known dislocations caused by the formation of the n⁺-type source layer 13 and the p⁺-type contact layer 14 that are generally formed by ion implantation with a high dose. Such a high dose of ion implantation makes amorphous at least part of the semiconductor substrate, and subsequent heat treatment for activation results in high-density formation of the first dislocations 200. By properly controlling the stresses in the n³¹ -type drift layer 1 including the mesa region, the positions of the first dislocations 200 are shifted and the second dislocations 201 are selectively formed. The positions where the second dislocations 201 are formed are located on the side closer to the second main surface than the n⁺-type source layer 13 and the p⁺-type contact layer 14 as shown in FIGS. 7 and 8.

### (4) Structure of Diode Area 20

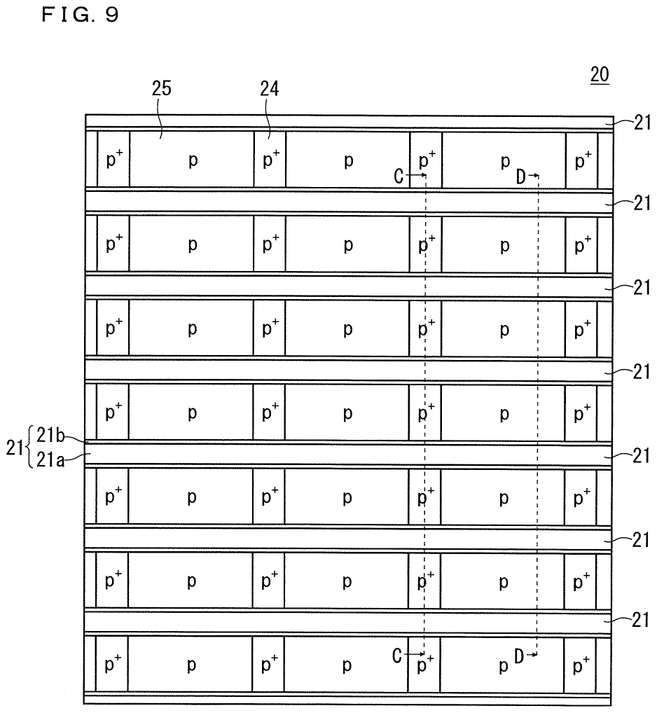

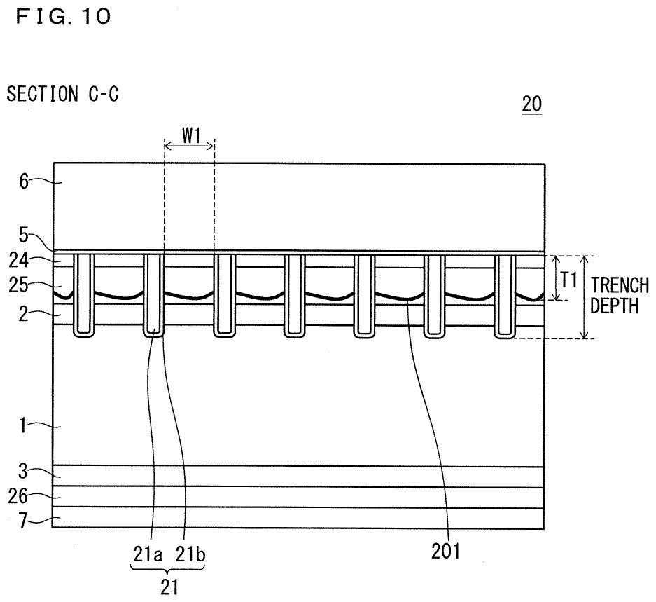

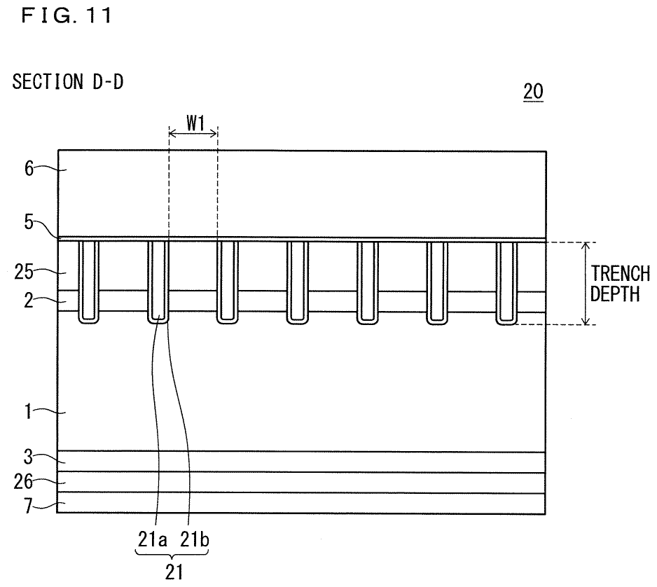

FIG. 9 is a partial enlarged plan view showing a configuration of the diode area of a semiconductor device that is an RC-IGBT. FIGS. 10 and 11 are sectional views showing the configuration of the diode area of the semiconductor device that is an RC-IGBT. FIG. 9 is an enlarged view of an area enclosed by a broken line 83 in the semiconductor device 100 shown in FIG. 4 or the semiconductor device 101 shown in FIG. 5. FIG. 10 is a sectional view of the semiconductor device 100 or 101 taken along a broken line C-C shown in FIG. 9. FIG. 11 is a sectional view of the semiconductor device 100 or 101 taken along a broken line D-D shown in FIG. 9.

Diode trench gates 21 extend from one end side of the diode area 20, which is the cell area, to the opposite other end side thereof along the first main surface of the semiconductor device 100 or 101. Each diode trench gate 21 is configured by providing a diode trench electrode 21a via a diode trench insulation film 21b in a trench formed in the semiconductor substrate in the diode area 20. The diode trench electrodes 21a face the n⁻-type drift layer 1 via the diode trench insulation films 21b. A p⁺-type anode contact layer 24 and a p-type anode layer 25 are provided between each pair of adjacent diode trench gates 21. The p⁺-type anode contact layer 24 is a semiconductor layer that contains, for example, boron or aluminum as a p-type impurity, and the concentration of the p-type impurity is in the range of 1.0E+15/cm³ to 1.0E+20/cm³. The p-type anode layer 25 is a semiconductor layer that contains, for example, boron or aluminum as a p-type impurity, and the concentration of the p-type impurity is in the range of 1.0E+12/cm³ to 1.0E+19/cm³. The p+-type anode contact layer 24 and the p-type anode layer 25 are alternated in the longitudinal direction of the diode trench gates 21.

FIG. 10 is a sectional view of the semiconductor device 100 or 101 taken along a broken line C-C in FIG. 8, and is also a sectional view of the diode area 20. In the diode area 20 as in the IGBT area 10, the semiconductor device 100 or 101 includes an n—type drift layer 1 configured by the semiconductor substrate. The n⁻-type drift layer 1 in the diode area 20 and the n⁻-type drift layer 1 in the IGBT area 10 are configured continuously to and integrally with each other by one semiconductor substrate. In FIG. 10, the semiconductor substrate ranges from the p⁺-type anode contact layer 24 to an n⁺-type cathode layer 26. In FIG. 10, the upper end of the p⁺-type anode contact layer 24 on the plane of the drawing is referred to as the first main surface of the semiconductor substrate, and the lower end of the n⁺-type cathode layer 26 on the plane of the drawing is referred to as the second main surface of the semiconductor substrate. The first main surface in the diode area 20 and the first main surface in the IGBT area 10 are in the same plane, and the second main surface in the diode area 20 and the second main surface in the IGBT area 10 are also in the same plane.

As shown in FIG. 10, in the diode area 20 as in the IGBT area 10, an n-type carrier storage layer 2 is provided on the first main surface side of the n⁻-type drift layer 1, and an n-type buffer layer 3 is provided on the second main surface side of the n⁻-type drift layer 1. The n-type carrier storage layer 2 and the n-type buffer layer 3 in the diode area 20 have the same configurations as the n-type carrier storage layer 2 and the n-type buffer layer 3 in the IGBT area 10. In the IGBT area 10 and the diode area 20, the n-type carrier storage layer 2 does not necessarily have to be provided, and a configuration is possible in which the n-type carrier storage layer 2 is not provided in the diode area 20 even in the case where the n-type carrier storage layer 2 is provided in the IGBT area 10. As in the IGBT area 10, the n⁻-type drift layer 1, the n-type carrier storage layer 2, and the n-type buffer layer 3 may be collectively referred to as a drift layer.

A p-type anode layer 25 is provided on the first main surface side of the n-type carrier storage layer 2. The p-type anode layer 25 is provided between the n—type drift layer 1 and the first main surface. The p-type anode layer 25 may have the same p-type impurity concentration as the p-type base layer 15 in the IGBT area 10 and may be formed simultaneously with the p-type base layer 15. A configuration is also possible in which the p-type impurity concentration of the p-type anode layer 25 may be made lower than the p-type impurity concentration of the p-type base layer 15 in order to reduce the amount of holes implanted in the diode area 20 during diode operation. The reduced amount of holes implanted during diode operation diode reduces recovery losses during diode operation.

The p⁺-type anode contact layer 24 is provided on the first main surface side of the p-type anode layer 25. The p-type impurity concentration of the p⁺-type anode contact layer 24 may be the same as or different from the p-type impurity concentration of the p⁺-type contact layer 14 in IGBT area 10. The p⁺-type anode contact layer 24 configures the first main surface of the semiconductor substrate. Note that the p⁺-type anode contact layer 24 is a region with a higher p-type impurity concentration than the p-type anode layer 25, and in the case where there is the need to distinguish between the p⁺-type anode contact layer 24 and the p-type anode layer 25, the p⁺-type anode contact layer 24 and the p-type anode layer 25 may be referred to individually. Alternatively, the p⁺-type anode contact layer 24 and the p-type anode layer 25 may also be collectively referred to as a p-type anode layer.

In the diode area 20, an n⁺-type cathode layer 26 is provided on the second main surface side of the n-type buffer layer 3. The n⁺-type cathode layer 26 is provided between the n⁻-type drift layer 1 and the second main surface. The n⁺-type cathode layer 26 is a semiconductor layer that contains, for example, arsenic or phosphorus as an n-type impurity, and the concentration of the n-type impurity is in the range of 1.0E+16/cm³ to 1.0E+21/cm³. As shown in FIG. 10, the n⁺-type cathode layer 26 is provided in part or the whole of the diode area 20. The n⁺-type cathode layer 26 configures the second main surface of the semiconductor substrate. Although not shown, a p-type cathode layer may be provided by further selectively implanting a p-type impurity into the region where the n⁺-type cathode layer 26 is formed as described above, so as to change part of the region where the n⁺-type cathode layer 26 is formed into a p-type semiconductor.

As shown in FIG. 10, trenches that extend from the first main surface of the semiconductor substrate through the p-type anode layer 25 to the n⁻-type drift layer 1 are formed in the diode area 20 of the semiconductor device 100 or 101. The diode trench gates 21 are configured by providing the diode trench electrode 21a via the diode trench insulation film 21b in each trench in the diode area 20. The diode trench electrodes 21a face the n⁻-type drift layer 1 via the diode trench insulation films 21b.

As shown in FIG. 10, a barrier metal 5 is provided on the diode trench electrodes 21a and the p⁺-type anode contact layer 24. The barrier metal 5 is in ohmic contact with and electrically connected to the diode trench electrodes 21a and the p⁺-type anode contact layer 24. The barrier metal 5 may have the same configuration as the barrier metal 5 in the IGBT area 10. An emitter electrode 6 is provided on the barrier metal 5. The emitter electrode 6 in the diode area 20 is formed continuously to the emitter electrode 6 in the IGBT area 10. As in the case of the IGBT area 10, the emitter electrode 6 may be in ohmic contact with the diode trench electrodes 21a and the p⁺-type anode contact layer 24 without via the barrier metal 5. In the illustration of FIG. 10, no interlayer insulation film 4 is provided on the diode trench electrodes 21a of the diode trench gates 21, but an interlayer insulation film 4 may be formed on the diode trench electrodes 21a of the diode trench gates 21. In the case where the interlayer insulation film 4 is formed on the diode trench electrodes 21a of the diode trench gates 21, the emitter electrode 6 and the diode trench electrodes 21a may be electrically connected to each other in a different section.

The diode trench gates 21 may also adopt a double gate structure in which the diode trench electrode 21a is divided into upper and lower sections.

A collector electrode 7 is provided on the second main surface side of the n⁺-type cathode layer 26. Like the emitter electrode 6, the collector electrode 7 in the diode area 20 is formed continuously to the collector electrode 7 provided in the IGBT area 10. The collector electrode 7 is in ohmic contact with and electrically connected to the n⁺-type cathode layer 26.

FIG. 11 is a sectional view of the semiconductor device 100 or 101 taken along a broken line D-D in FIG. 9 and is also a sectional view of the diode area 20. This sectional view is different from the sectional view taken along the broken line C-C in FIG. 10 in that there is no p⁺-type anode contact layer 24 between the p-type anode layer 25 and the barrier metal 5, and the p-type anode layer 25 configures the first main surface of the semiconductor substrate. That is, the p⁺-type anode contact layer 24 shown in FIG. 10 is selectively provided on the first main surface side of the p-type anode layer 25.

As shown in FIG. 10, second dislocations 201 are also arranged on the second main surface side of the p+-type anode contact layer 24 in the diode area 20. The p+-type anode contact layer 24 includes known first dislocations 200 which are not shown. The second dislocations 201 are crystal defects that expand three-dimensionally also in the depth direction on the plane of the drawing, and have an overall length L1 greater than the mesa width W1. The overall length L1 does not refer to the length of a curve in plan view, but refers to the length of a curve in stereoscopic vision. It is not easy to measure the length of the curve in stereoscopic vision, but in the case where the curve extends also in the depth direction on the plane of the drawing in FIG. 10, in general, it can be safely said that the following inequality is satisfied: “linear dimensions in plan view”<“curve length in plan view”<“curve length in stereoscopic vision”. Here, if “curve length in plan view”=“curve length in stereoscopic vision” is satisfied, this indicates that the dislocations do not extend in the depth direction on the plane of the drawing. If “linear dimensions in plan view”=“curve length in plan view” is satisfied, this indicates that the dislocations have a linear shape and do not extend in the depth direction on the plane of the drawing.

The second dislocations 201 are selectively arranged in positions that are three-dimensionally different from the positions of the first dislocations 200. The first dislocations 200 are known dislocations caused by the formation of the p⁺-type anode contact layer 24 that is generally formed by ion implantation with a high dose. Such a high-dose ion implantation makes amorphous at least part of the semiconductor substrate, and subsequent heat treatment for activation results in high-density formation of the first dislocations 200. By properly controlling the stresses in the n⁻-type drift layer 1 including the mesa region, the positions of the first dislocations 200 are shifted and the second dislocations 201 are selectively formed. The positions where the second dislocations 201 are formed are located on the side closer to the second main surface than the p⁺-type anode contact layer 24 as shown in FIG. 10. Since the p+-type anode contact layer 24 is not formed in the area corresponding to the section shown in FIG. 11, the first dislocations 200 are also not formed in this area.

(5) Boundary Area between IGBT Area 10 and Diode Area 20

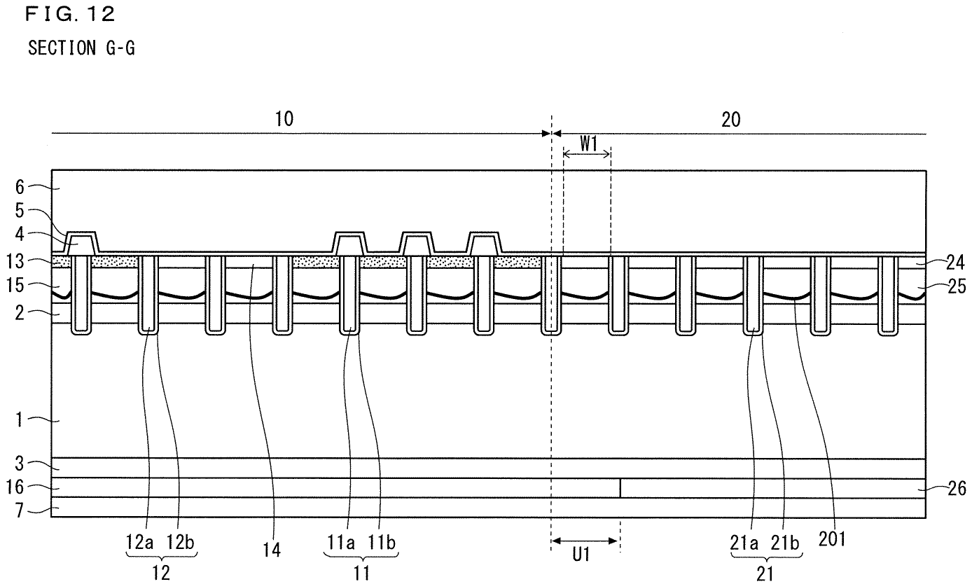

FIG. 12 is a sectional view showing a configuration of the boundary between one IGBT area and one diode area of the semiconductor device that is an RC-IGBT. FIG. 12 is a sectional view of the semiconductor device 100 shown in FIG. 4 or the semiconductor device 101 shown in FIG. 5 taken along a broken line G-G.

As shown in FIG. 12, the p-type collector layer 16 provided on the second main surface side in the IGBT area 10 extends off the boundary between the IGBT area 10 and the diode area 20 toward the diode area 20 by a distance U1. The presence of the p-type collector layer 16 that extends off the boundary toward the diode area 20 in this way increases the distance between the n⁺-type cathode layer 26 and the active trench gates 11 in the diode area 20. Thus, even in the case where a gate driving voltage is applied to the gate trench electrodes 11a during freewheeling diode operation, it is possible to prevent the current from flowing to the n⁺-type cathode layer 26 from the channel formed adjacent to the active trench gates 11 in the IGBT area 10. For example, the distance U1 may be 100 μm. Depending on the application of the semiconductor device 100 or 101 that is an RC-IGBT, the distance U1 may be zero or smaller than 100 μm.

As shown in FIG. 12, first dislocations 200 may also be arranged in the boundary between the diode area 20 and the IGBT area 10, the boundary including the area corresponding to the distance U1 (the area in which the p-type collector layer 16 extends off the IGBT area 10). In this case, the recovery capacity can be increased by trapping minority carriers (here, holes) during diode turn-off. Here, the boundary between the IGBT area 10 and the diode area 20 refers to an area that minority carriers in diodes reach during turn-off, and for example, may be greater in width than the distance U1. More quantitatively, the IGBT area 10 and the diode area 20 refers to an area that is within ±100 μm from the end of the p-type collector layer 16.

### (6) Structure of Termination Area 30

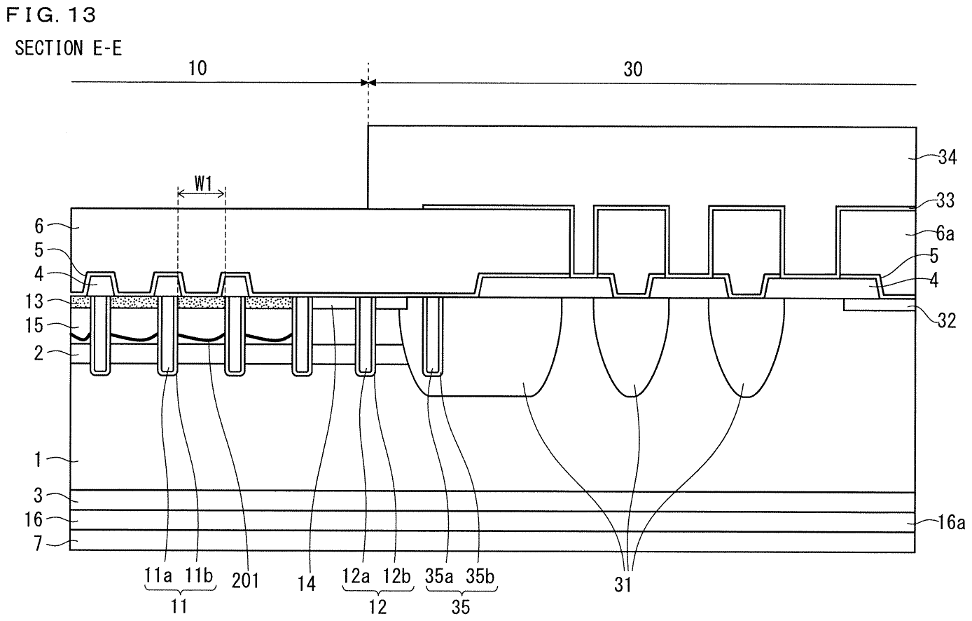

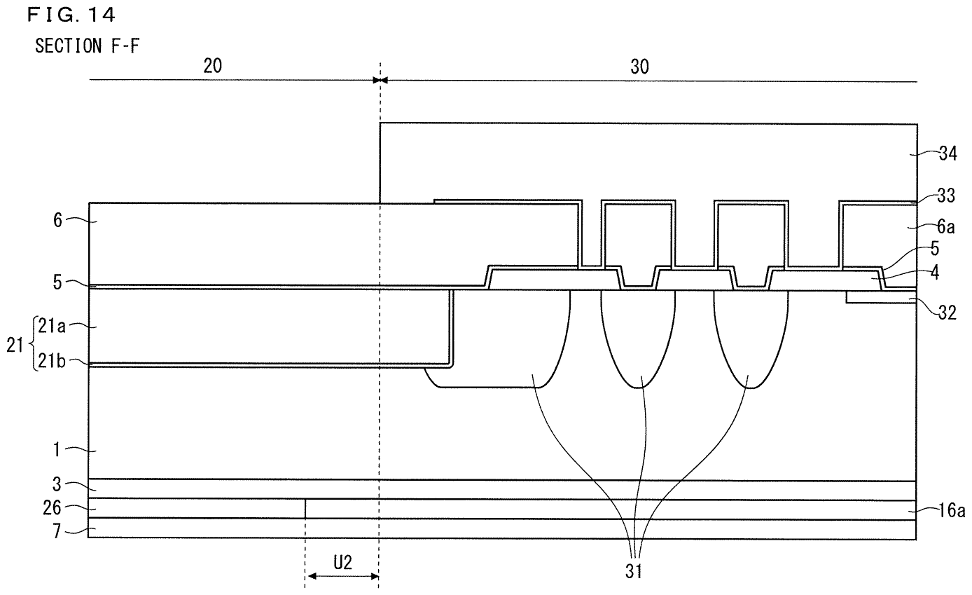

FIGS. 13 and 14 are sectional views showing a configuration of the termination area of the semiconductor device that is an RC-IGBT. FIG. 13 is a sectional view taken along a broken line E-E in FIG. 4 or 5, and is also a sectional view ranging from one IGBT area 10 to the termination area 30. FIG. 14 is a sectional view taken along a broken line F-F in FIG. 4, and is also a sectional view ranging from one diode area 20 to the termination area 30.

As shown in FIGS. 13 and 14, the termination area 30 of the semiconductor device 100 includes the n⁻-type drift layer 1 between the first and second main surfaces of the semiconductor substrate. The first and second main surfaces in the termination area 30 are respectively in the same planes as the first and second main surfaces in the IGBT area 10 and the diode area 20. The n—type drift layer 1 in the termination area 30 has the same configuration as the n⁻-type drift layer 1 in the IGBT area 10 and the n⁻- type drift layer 1 in the diode area 20, and is formed continuously to and integrally with the n⁻-type drift layer 1 in the IGBT area 10 and the n⁻-type drift layer 1 in the diode area 20.

A p-type terminal well layer 31 is provided on the first main surface side of the n⁻-type drift layer 1, i.e., between the n⁻-type drift layer 1 and the first main surface of the semiconductor substrate. The p-type terminal well layer 31 is a semiconductor layer that contains, for example, boron or aluminum as a p-type impurity, and the concentration of the p-type impurity is in the range of 1.0E+14/cm³ to 1.0E+19/cm³. The p-type terminal well layer 31 is provided to surround the cell area including the IGBT area 10 and the diode area 20. The p-type terminal well layer 31 is provided in the shape of a plurality of rings, and the number of p-type terminal well layers 31 to be provided is selected as appropriate depending on the withstand-voltage design of the semiconductor device 100 or 101. Moreover, an n⁺-type channel stopper layer 32 is provided on the outer edge side of the p-type terminal well layer 31 so as to surround the p-type terminal well layer 31.

In the termination area 30, a terminal dummy trench gate 35 is provided in the p-type terminal well layer 31. The terminal dummy trench gate 35 is configured by providing a terminal dummy trench electrode 35a via a terminal dummy trench insulation film 35b in a trench formed in the semiconductor substrate.

The p-type terminal collector layer 16a is provided between the n⁻-type drift layer 1 and the second main surface of the semiconductor substrate. The p-type terminal collector layer 16a is formed continuously to and integrally with the p-type collector layer 16 provided in the cell area. Thus, the p-type terminal collector layer 16a may be included in and referred to as the p-type collector layer 16. In the configuration in which the termination area 30 is adjacent to the diode area 20 as in the semiconductor device 100 shown in FIG. 4, the end of the p-type terminal collector layer 16a on the side closer to the diode are 20 extends off toward the diode area 20 by a distance U2 as shown in FIG. 14. In this way, the presence of the p-type terminal collector layer 16a that extends off toward the diode area 20 increases the distance between the p-type terminal well layer 31 and the n+-type cathode layer 26 in the diode area 20 and prevents the p-type terminal well layer 31 from operating as the anode of the diode. For example, the distance U2 may be 100 μm.

The collector electrode 7 is provided on the second main surface of the semiconductor substrate. The collector electrode 7 is continuously and integrally formed from the cell area including the IGBT area 10 and the diode area 20 to the termination area 30. Meanwhile, the emitter electrode 6 continuous from the cell area and terminal electrodes 6a that are separated from the emitter electrode 6 are provided on the first main surface of the semiconductor substrate in the termination area 30.

The emitter electrode 6 and the terminal electrodes 6a are electrically connected to each other via a semi-insulation film 33. For example, the semi-insulation film 33 may be semi-insulating silicon nitride (sinSiN). The terminal electrodes 6a are electrically connected to the p-type terminal well layer 31 and the n⁺-type channel stopper layer 32 via contact holes formed in the interlayer insulation film 4 provided on the first main surface in the termination area 30. In the termination area 30, a terminal protective film 34 is further provided to cover the emitter electrode 6, the terminal electrodes 6a, and the semi-insulation film 33. The terminal protective film 34 may be formed of, for example, polyimide. The terminal protective film 34 may be formed without via the semi-insulation film 33.

In FIGS. 13 and 14, the p-type terminal well layer 31 is formed to a region closer to the second main surface than the active trench gates 11, the dummy trench gates 12, or the terminal dummy trench gate 35, but the p-type terminal well layer 31 may be provided in a position more remote from the second main surface than the active trench gates 11, the dummy trench gates 12, or the terminal dummy trench gate 35. In other words, the p-type terminal well layer 31 may be shallower than the active trench gates 11, the dummy trench gates 12, or the terminal dummy trench gates 35. However, if the p-type terminal well layer 31 is shallower than the terminal dummy trench gate 35, electric field strength on the second main surface side of the terminal dummy trench gate 35 will be increased. Thus, in order to avoid this, the terminal dummy trench gate 35 may be formed shallower than the active trench gates 11 or the dummy trench gates 12.

The number of terminal dummy trench gates 35 is not limited to one and may be greater than or equal to one and less than or equal to ten. In the case where there are a plurality of terminal dummy trench gates 35, the depths of the terminal dummy trench gates 35 may be gradually reduced in a direction toward the outside (in a direction from the cell area toward the termination area) in order to gradually reduce electric field strength during turn-off. That is, the more outward the terminal dummy trench gates 35 are located, the shallower the terminal dummy trench gates 35 are. It is desirable that no second dislocations 201 are formed in the terminal dummy trench gate 35 or the termination area 30.

### Manufacturing Method Common to Embodiments

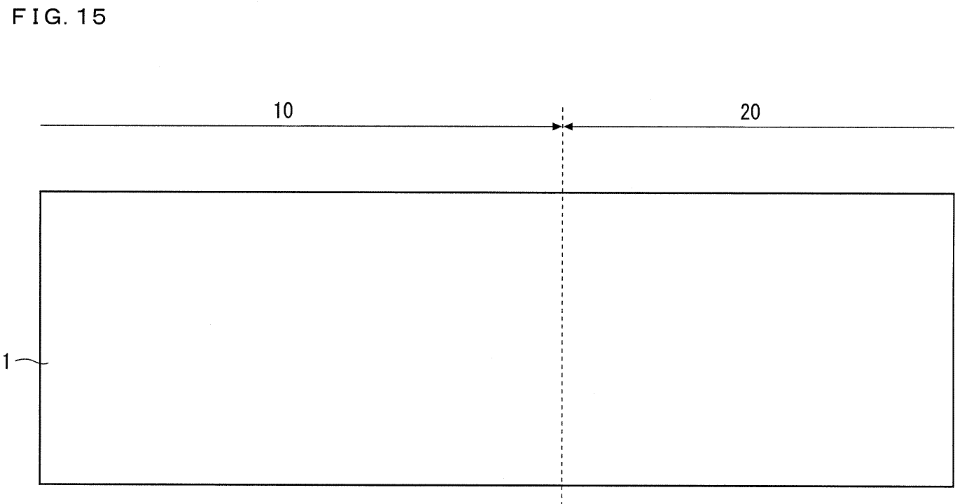

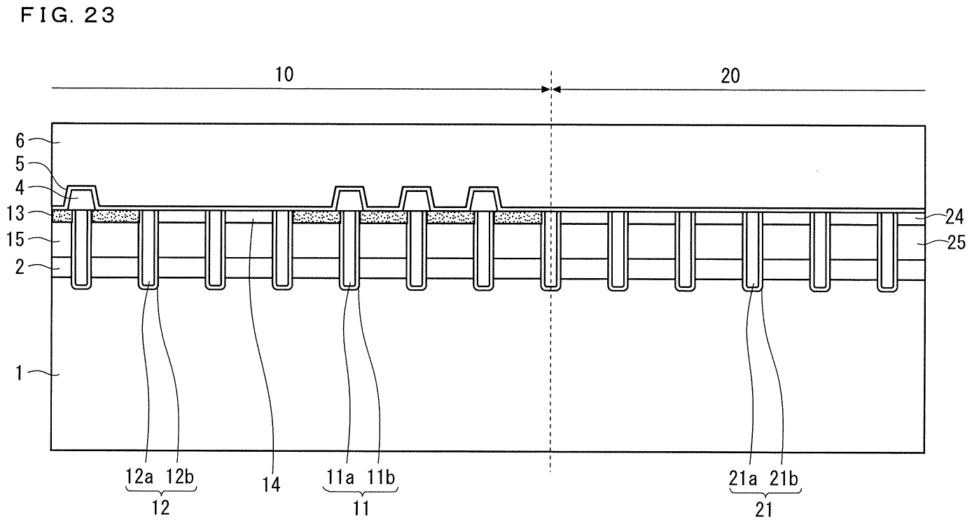

FIGS. 15 to 26 are diagrams showing the method of manufacturing a semiconductor device that is an RC-IGBT. FIGS. 15 to 22 show the steps of forming the front side of the semiconductor device 100 or 101, and FIGS. 23 to 26 show the steps of forming the back side of the semiconductor device 100 or 101.

First, a semiconductor substrate that configures the n⁻-type drift layer 1 is prepared as shown in FIG. 15. For example, the semiconductor substrate may be a so-called floating zone (FZ) wafer produced by a FZ method or a so-called magnetic applied Czochralki (MCZ) wafer produced by a (MCZ) method, and may be an n-type wafer containing an n-type impurity. The concentration of the n-type impurity contained in the semiconductor substrate is selected as appropriate depending the withstand voltage of a semiconductor device to be produced, and for example, for a semiconductor device with a withstand voltage of 1200V, the concentration of the n-type impurity is controlled such that the n—type drift layer 1 configuring the semiconductor substrate has a resistivity of approximately 40 Ω·cm to 120 Ω·cm. With the method of manufacturing a semiconductor substrate, various impurities such as phosphorus, arsenic, nitrogen, boron, oxygen, or carbon are mixed into the semiconductor substrate, but this is immaterial as long as the resistivity is controlled to achieve the desired withstand voltage. In order to control the resistivity, compound defects occurring with each impurity element, interstitial silicon, or lattice vacancies may be used. As shown in FIG. 15, the semiconductor substrate as a whole is the n⁻-type drift layer 1 in the step of preparing the semiconductor substrate, but the semiconductor device 100 or 101 is manufactured by implanting p- or n-type impurity ions from the first or second main surfaces of the semiconductor substrate and diffusing the impurity ions throughout the semiconductor substrate by subsequent heat treatment or the like so as to form a p- or n-type semiconductor layer.

As shown in FIG. 15, the semiconductor substrate configuring the n⁻-type drift layer 1 includes an area that becomes an IGBT area 10 and a diode area 20. Although not shown, the semiconductor substrate also includes an area that becomes the termination area 30 around the area that becomes the IGBT area 10 and the diode area 20. The following description is mainly given regarding the method of manufacturing configurations of the IGBT area 10 and the diode area 20 of the semiconductor device 100 or 101. The termination area 30 of the semiconductor device 100 or 101 may be produced by a known manufacturing method. For example, in the case where an FLR that includes the p-type terminal well layer 31 is formed as a withstand-voltage retaining structure in the termination area 30, the FLR may be formed by implanting p-type impurity ions before processing the IGBT area 10 and the diode area 20 of the semiconductor device 100 or 101, or may be formed by implanting p-type impurity ions simultaneously with when p-type impurities are implanted in the IGBT area 10 or the diode area 20 of the semiconductor device 100 or 101.

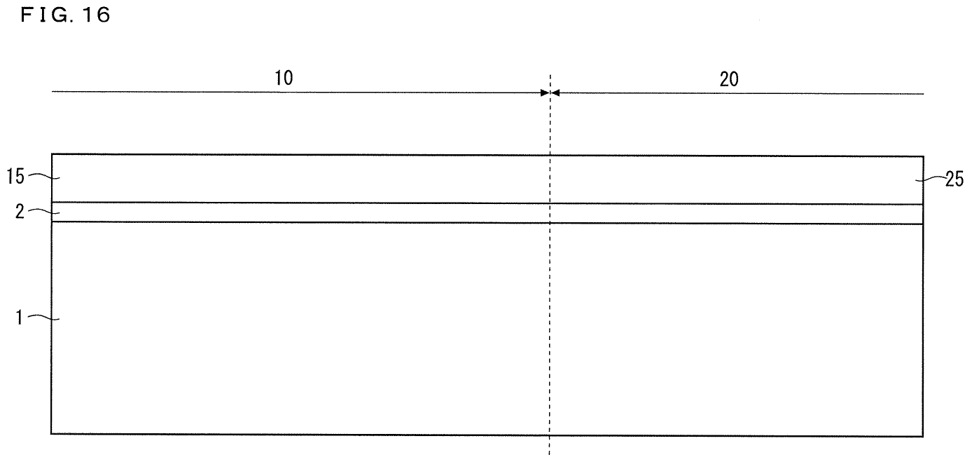

Then, as shown in FIG. 16, the n-type carrier storage layer 2 is formed by implanting an n-type impurity such as phosphorus (P) from the first main surface side of the semiconductor substrate. Moreover, the p-type base layer 15 and the p-type anode layer 25 are formed by implanting a p-type impurity such as boron (B) from the first main surface side of the semiconductor substrate. The n-type carrier storage layer 2, the p-type base layer 15, and the p-type anode layer 25 are formed by diffusing impurity ions by heat treatment after implantation of the impurity ions into the semiconductor substrate. Since the n-and p-type impurity ions are implanted after mask processing is performed on the first main surface of the semiconductor substrate, those layers are selectively formed on the first main surface side of the semiconductor substrate. The n-type carrier storage layer 2, the p-type base layer 15, and the p-type anode layer 25 are formed in the IGBT area 10 and the diode area 20 and connected to the p-type terminal well layer 31 in the termination area 30. The mask processing as used herein refers to processing for applying a resist on the semiconductor substrate, forming openings in predetermined regions of the resist by a photomechanical process, and forming a mask on the semiconductor substrate to perform ion implantation or etching on the predetermined regions of the semiconductor substrate through the openings.

The p-type base layer 15 and the p-type anode layer 25 may be formed simultaneously by implanting p-type impurity ions. In this case, the p-type base layer 15 and the p-type anode layer 25 have the same configuration with the same depth and the same p-type impurity concentration. The depths or the p-type impurity concentrations of the p-type base layer 15 and the p-type anode layer 25 may be differentiated by implanting p-type impurity ions separately into the p-type base layer 15 and the p-type anode layer 25 through mask processing.

The p-type terminal well layer 31 formed in a different section may be formed simultaneously with the p-type anode layer 25 by implanting p-type impurity ions. In this case, the p-type terminal well layer 31 and the p-type anode layer 25 may have the same configuration with the same depth and the same p-type impurity concentration. It is also possible to differentiate the p-type impurity concentrations of the p-type terminal well layer 31 and the p-type anode layer 25 by implanting p-type impurity ions simultaneously into the p-type terminal well layer 31 and the p-type anode layer 25. In this case, the open area ratio of either or both of the masks for the p-type terminal well layer 31 and the p-type anode layer 25 may be changed by using a mesh mask.

The depths and the p-type impurity concentrations of the p-type terminal well layer 31 and the p-type anode layer 25 may also be differentiated by implanting impurity ions separably into the p-type terminal well layer 31 and the p-type anode layer 25 through mask processing.

It is also possible to form the p-type terminal well layer 31, the p-type base layer 15, and the p-type anode layer 25 simultaneously by ion implantation.

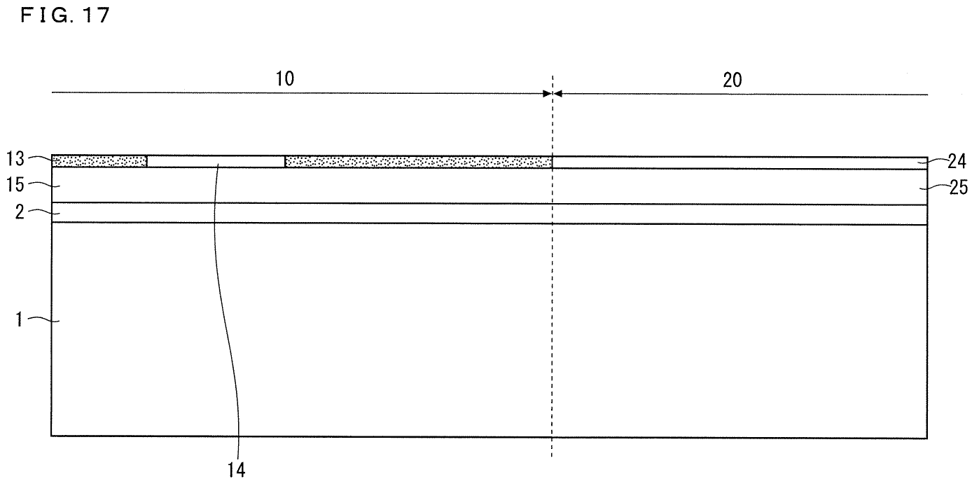

Then, as shown in FIG. 17, the n⁺-type source layer 13 is formed on the first main surface side of the p-type base layer 15 in the IGBT area 10 by selectively implanting n-type impurity ions through mask processing. For example, the n-type impurity to be implanted may be arsenic (As) or phosphorus (P). Moreover, through mask processing, the p⁺-type contact layer 14 is formed on the first main surface side of the p-type base layer 15 in the IGBT area 10 by selectively implanting a p-type impurity, and the p⁺-type anode contact layer 24 is formed on the first main surface side of the p-type anode layer 25 in the diode area 20 by selectively implanting a p-type impurity. For example, the p-type impurities to be implanted may be boron (B) or aluminum (Al).

Since the n⁺-type source layer 13 or the p⁺-type contact layer 14 has a high impurity concentration, in general, the implantation dose is high during ion implantation processing. As a result of the high-dose ion implantation processing, the regions that allow passage of the implanted elements have high defect densities and, depending on conditions, may become amorphous due to disappearance of crystallinity. Such implanted regions or amorphous layers are generally improved by annealing, which is performed for the purpose of activating implanted impurities. However, there is no need to restore such regions to regions with low defect densities such as before the ion implantation, and defects may be left in the range in which electrical characteristics are not affected. The remaining defective regions generally include silicon lattice vacancies, interstitial silicon atoms, silicon atomic pores, complexes of silicon lattice vacancies and interstitial silicon, and dislocations with mismatched crystal faces. Although it is difficult to observe fine point defects such as lattice vacancies or interstitial atoms, dislocations are easy to observe by a generally-used technique (e.g., with a scanning tunneling microscope: STM) and are known as the first dislocations 200. The first dislocations 200 exist in any region of the n⁺-type source layer 13, the p⁺-type contact layer 14, and the p⁺-type anode contact layer 24 in FIGS. 17 to 26, but are not shown.

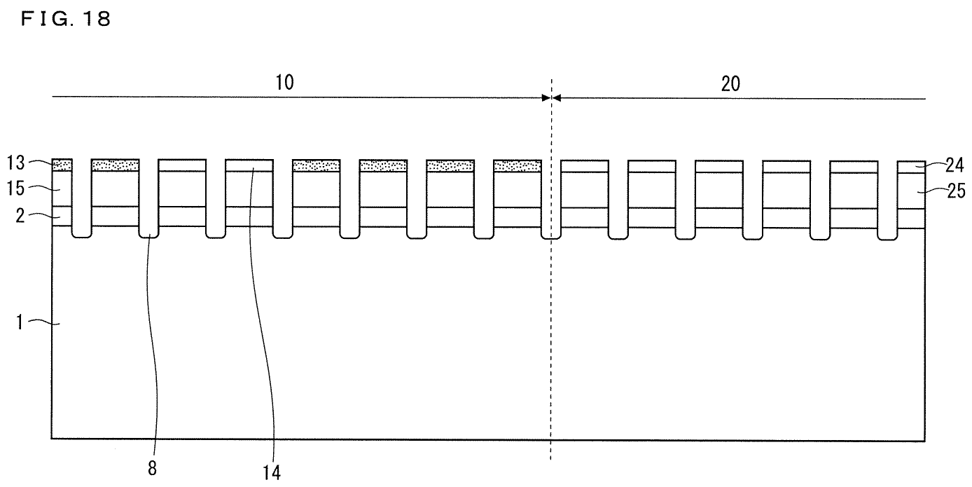

Then, as shown in FIG. 18, trenches 8 are formed from the first main surface side of the semiconductor substrate through the p-type base layer 15 and the p-type anode layer 25 to the n⁻-type drift layer 1. In the IGBT area 10, the trenches 8 that penetrate the n+-type source layer 13 have side walls that configure part of the n⁺-type source layer 13. The trenches 8 may be formed by firstly depositing an oxide film such as SiO₂ on the semiconductor substrate, forming openings in portions of the oxide film where the trenches 8 are formed, through mask processing, and etching the semiconductor substrate by using the oxide film having openings as a mask. In FIG. 18, the trenches 8 are formed with the same pitches in the IGBT area 10 and the diode area 20, but the pitches of the trenches 8 may be differentiated between the IGBT area 10 and the diode area 20. For stress design, the IGBT area 10 may include a region where the trenches 8 have different pitches, the diode area 20 may include a region where the trenches 8 have different pitches, or the trenches 8 may be designed to have an arbitrary depth. The pitches of the trenches 8 may be changed as appropriate by using a mask pattern during mask processing. Moreover, a micro loading effect of changing the depths of trenches may be used depending on the mask pattern.

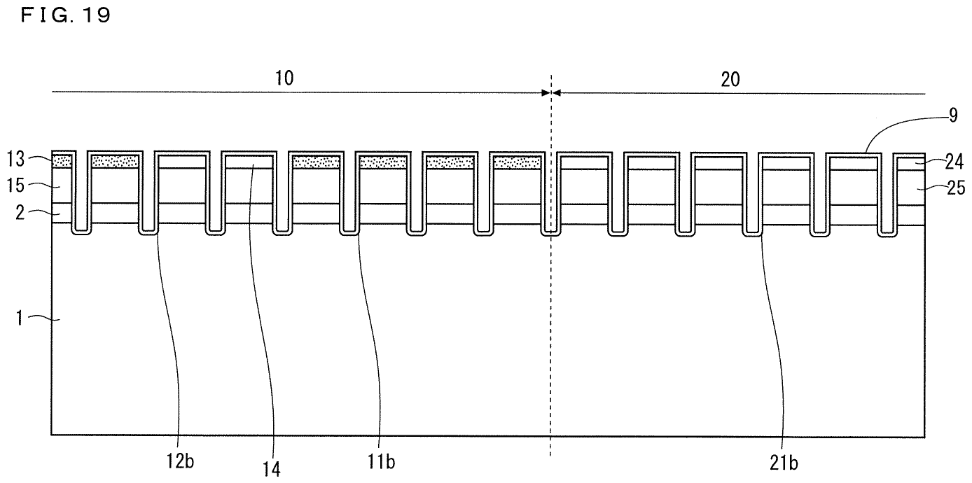

Then, as shown in FIG. 19, an oxide film 9 is formed on the inner walls of the trenches 8 and on the first main surface of the semiconductor substrate by heating the semiconductor substrate in an oxygen-containing atmosphere. Out of the oxide film 9 formed on the inner walls of the trenches 8, the oxide film 9 formed in the trenches 8 in the IGBT area 10 serves as the gate trench insulation films 11b of the active trench gates 11 and the dummy trench insulation films 12b of the dummy trench gates 12. The oxide film 9 formed in the trenches 8 in the diode area 20 serves as the diode trench insulation films 21b. The oxide film 9 formed in the trenches 8 in the termination area 30 serves as the terminal dummy trench insulation film 35b. The oxide film 9 formed on the main surface of the semiconductor substrate is removed by a subsequent process.

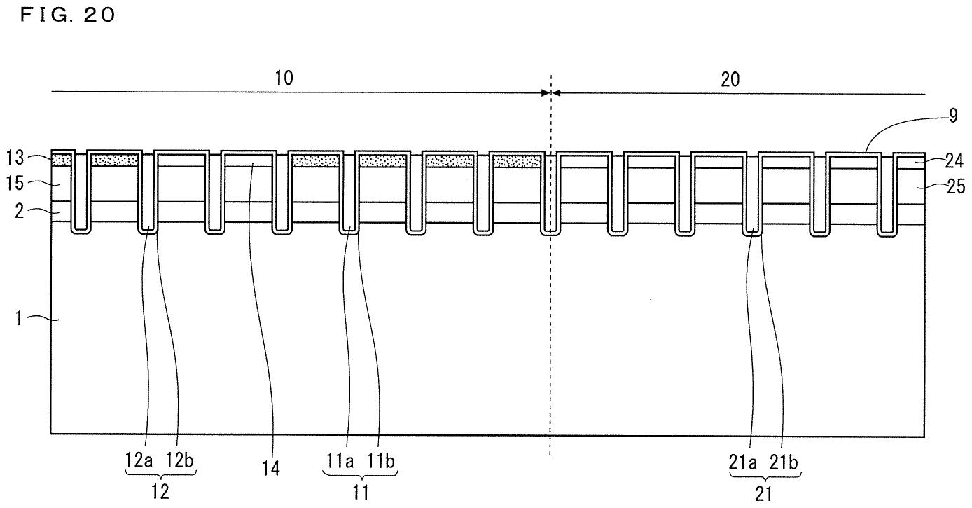

Then, as shown in FIG. 20, the gate trench electrodes 11a, the dummy trench electrodes 12a, the diode trench electrodes 21a, and the terminal dummy trench electrode 35a are formed by depositing polysilicon doped with an n- or p-type impurity in the trenches 8 whose inner walls have the oxide film 9 formed thereon, by chemical vapor deposition (CVD) or the like. In this way, the active trench gates 11, the dummy trench gates 12, the diode trench gates 21, and the terminal dummy trench gate 35 are formed.

Stresses in the n⁻-type drift layer 1 including the mesa region are controlled during the step of forming the active trench gates 11, the dummy trench gates 12, the diode trench gates 21, and the terminal dummy trench gate 35 (which are hereinafter collectively referred to as “trench gates”). In order to increase the stresses, for example, it is effective to set design parameters such as deepening the trench gates, narrowing the pitches of the trenches, increasing the thickness of the oxide film 9 that becomes the gate trench insulation films 11b, the dummy trench insulation films 12b, the diode trench insulation films 21b, and the terminal dummy trench insulation film 35b, adopting a double gate structure as the structure of the trench gates, or increasing the thickness of the oxide film that comes in contact with the n⁻-type drift layer 1 in the double gate structure. The stresses in the n⁻-type drift layer 1 including the mesa region is easily measurable by TEM analysis or a convergent beam electron diffraction (CBED) method. In order to arrange the second dislocations 201 at arbitrary positions, a designer controls the stresses in the n⁻-type drift layer 1 including the mesa region.

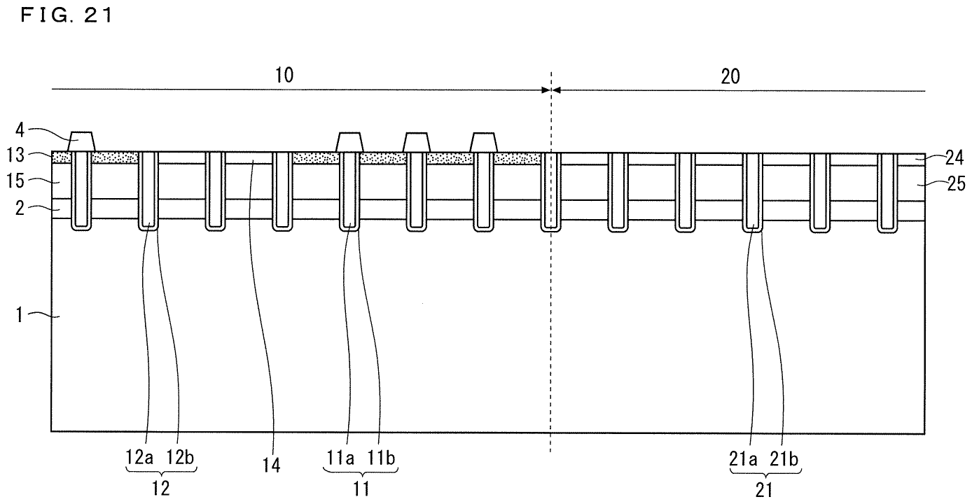

Then, as shown in FIG. 21, the interlayer insulation film 4 is formed on the gate trench electrodes 11a of the active trench gates 11 in the IGBT area 10, and thereafter the oxide film 9 formed on the first main surface of the semiconductor substrate is removed. The interlayer insulation film 4 may, for example, be SiO₂. Then, contact holes are formed in the interlayer insulation film 4 deposited through mask processing. The contact holes are formed on the n⁺-type source layer 13, on the p⁺-type contact layer 14, on the p⁺-type anode contact layer 24, on the dummy trench electrodes 12a, and on the diode trench electrodes 21a.

After the formation of the interlayer insulation film 4, heat treatment may be additionally conducted. The heat treatment serves to ensure thermal stability of the interlayer insulation film 4 and also serves as an impetus to arrange the second dislocations 201 in the n⁻-type drift layer 1 under stress control. By using the stresses and thermal energy in the n—type drift layer 1 as a power source, the first dislocations 200 formed on the first main surface side by high-dose implantation can be arranged in arbitrary positions. The arbitrary positions as used herein refer to regions different from the regions of the first dislocations 200 and are specifically located on the side closer to the second main surface than the n⁺-type source layer 13, the p⁺-type contact layer 14, and the p⁺-type anode contact layer 24. The effect of arranging the second dislocations 201 within the semiconductor device is as described previously. Here, the second dislocations 201 formed by this method have the overall length L1 longer than the mesa width W1 and are curved in a convex shape toward the second main surface. Increasing the overall length L1 of the second dislocation 201 to become greater than the mesa width W1 improves the carrier trapping effect. Moreover, shaping the second dislocation 201 in a convex shape toward the second main surface improves the effect of trapping carriers in the n⁻-type drift layer 1.

The technique for arranging the second dislocations 201 in arbitrary positions by controlling the stresses in the n⁻-type drift layer 1 has never been known before. As compared with irradiation with charged particles, which is a conventional lifetime reducing method, this technique takes stresses into account at the design state, thus having the advantage of forming lifetime reducing regions in arbitrary positions without any additional step required for lifetime control.

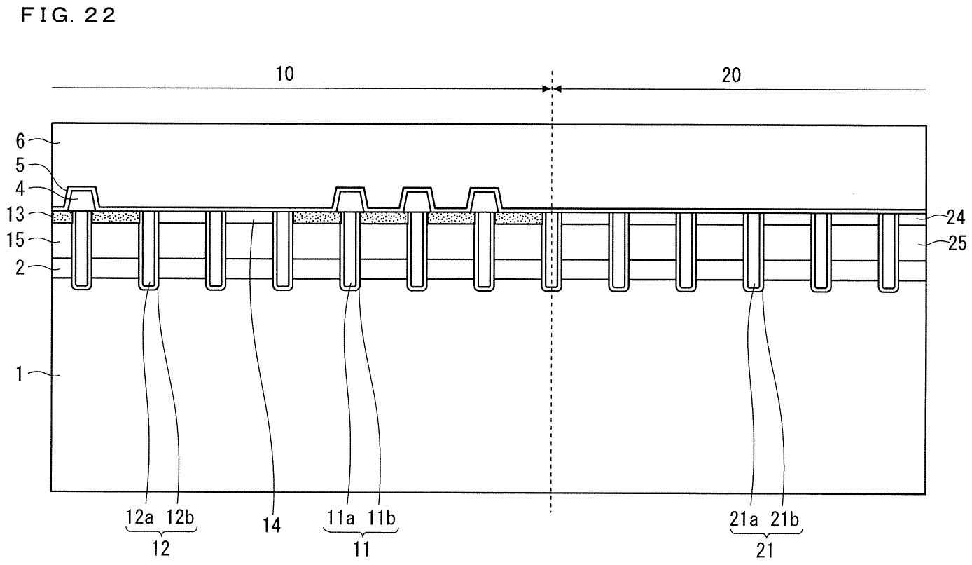

Then, as shown in FIG. 22, the barrier metal 5 is formed on the first main surface of the semiconductor substrate and on the interlayer insulation film 4, and the emitter electrode 6 is further formed on the barrier metal 5. The barrier metal 5 is formed by depositing titanium nitride by CVD or physical vapor deposition (PDV).

The emitter electrode 6 may be formed by, for example, depositing an aluminum-silicon alloy (Al—Si-based alloy) or a material composed primarily of copper on the barrier metal 5 by PVD such as sputtering or vacuum deposition. The emitter electrode 6 may be formed by further forming a nickel alloy (Ni alloy) on the deposited aluminum-silicon alloy by electroplating or electroless plating. In the case of forming the emitter electrode 6 by plating, a thick metal film can easily be formed as the emitter electrode 6. Thus, it is possible to increase the thermal capacity of the emitter electrode 6 and to improve heat resistance. Note that in the case of further forming a nickel alloy by plating after the formation of the emitter electrode 6 of an aluminum-silicon alloy by PVD, the plating for forming the nickel alloy may be performed after machining is conducted on the second main surface side of the semiconductor substrate.

Then, as shown in FIG. 23, the second main surface side of the semiconductor substrate is subjected to grinding as to reduce the thickness of the semiconductor substrate to the desired thickness. The thickness of the semiconductor substrate that has undergone grinding may be in the range of, for example, 60 μm to 200 μm.

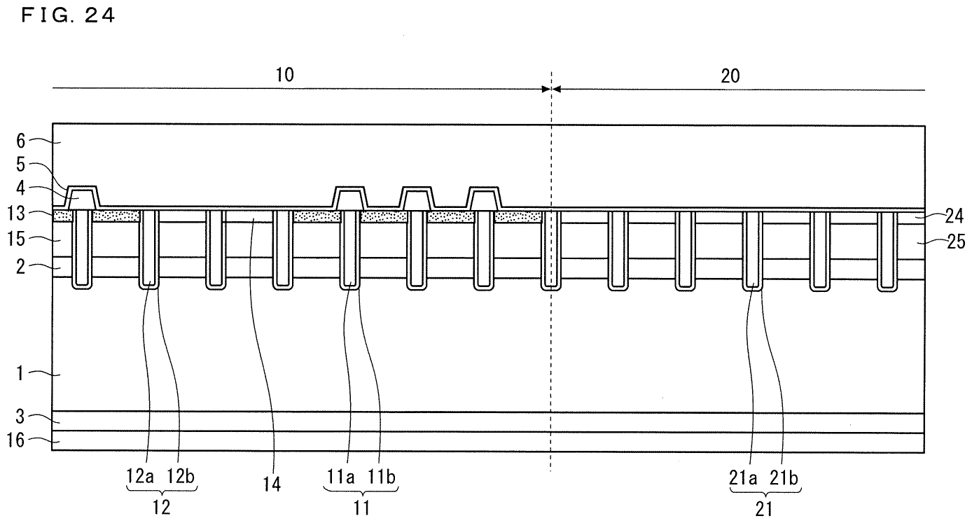

Then, as shown in FIG. 24, the n-type buffer layer 3 is formed by implanting an n-type impurity from the second main surface side of the semiconductor substrate. Moreover, the p-type collector layer 16 is formed by implanting a p-type impurity from the second main surface side of the semiconductor substrate. The n-type buffer layer 3 may be formed in the IGBT area 10, the diode area 20, and the termination area 30, or may be formed only in the IGBT area 10 or the diode area 20.

The n-type buffer layer 3 may be formed by, for example, implanting phosphorus (P) ions. Alternatively, the n-type buffer layer 3 may be formed by implanting proton (H+). Yet alternatively, the n-type buffer layer 3 may be formed by implanting both of proton and phosphorus. Proton can be implanted from the second main surface of the semiconductor substrate to a deep position with relatively low acceleration energy. The implantation depth of proton can be changed relatively easily by changing the acceleration energy. Therefore, if proton is implanted multiple times while changing the acceleration energy during formation of the n-type buffer layer 3, the n-type buffer layer 3 can be formed to a greater width in the depth direction of the semiconductor substrate than in the case of forming the n-type buffer layer 3 of phosphorus.

As compared with proton, phosphorus has the property of improving the activation ratio of an n-type impurity. Thus, even if the thickness of the semiconductor substrate is reduced by forming the n-type buffer layer 3 of phosphorus, it is possible to more reliably suppress the occurrence of punch-through of the depletion layer. In order to further reduce the thickness of the semiconductor substrate, the n-type buffer layer 3 is preferably formed by implanting both proton and phosphorus. At this time, proton is implanted to a deeper position than phosphorus from the second main surface.

The p-type collector layer 16 may be formed by, for example, implanting boron (B). The p-type collector layer 16 is also formed in the termination area 30, and the p-type collector layer 16 in the termination area 30 becomes the p-type terminal collector layer 16a. By implanting ions from the second main surface side of the semiconductor substrate and thereafter subjecting the second main surface to laser annealing by laser irradiation, the implanted boron is activated to form the p-type collector layer 16. At this time, phosphorus for the n-type buffer layer 3, which has been implanted to a relatively shallow position from the second main surface of the semiconductor substrate, is also activated simultaneously. Meanwhile, proton is activated at a relatively low annealing temperature of, for example, 350° C. to 500° C. Thus, it is necessary to keep in mind that, after the implantation of proton, the temperature of the semiconductor substrate as a whole shall not become beyond the range of 350° C. to 500° C. during steps other than the step for activating proton. Since laser annealing allows only the second main surface and its vicinity of the semiconductor substrate to become a higher temperature, it can be used to activate n-and p-type impurities even after the implantation of proton.

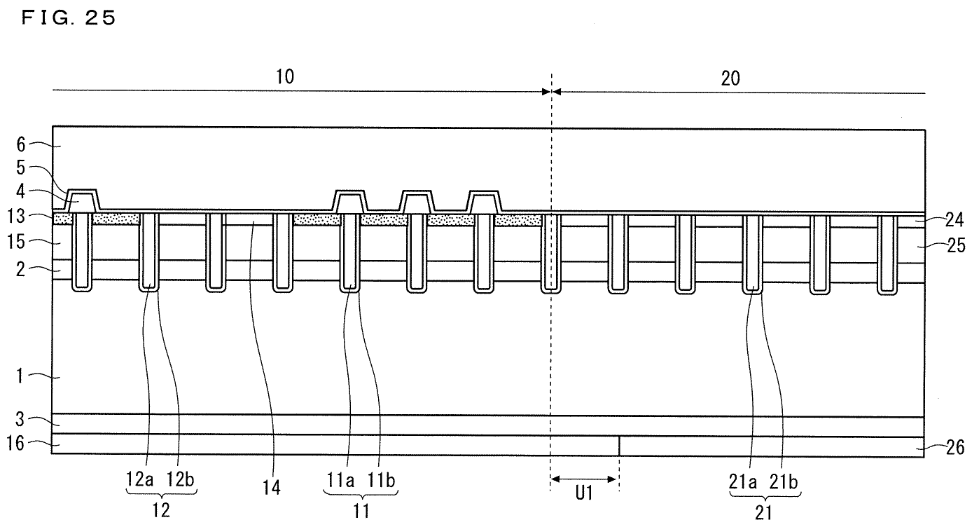

Then, as shown in FIG. 25, the n+-type cathode layer 26 is formed in the diode area 20. The n⁺-type cathode layer 26 may be formed by, for example, implanting phosphorus (P). As shown in FIG. 25, phosphorus is selectively implanted from the second main surface side through mask processing so that the boundary between the p-type collector layer 16 and the n⁺-type cathode layer 26 is located at a position spaced by the distance U1 from the boundary between the IGBT area 10 and the diode area 20 toward the diode area 20. The amount of the n-type impurity implanted to form the n⁺-type cathode layer 26 is greater than the amount of the p-type impurity implanted to form the p-type collector layer 16. FIG. 25 shows that the p-type collector layer 16 and the n⁺-type cathode layer 26 have the same depth from the second main surface, but the depth of the n⁺-type cathode layer 26 is greater than or equal to the depth of the p-type collector layer 16. The region where the n⁺-type cathode layer 26 is formed needs to be an n-type semiconductor by implanting an n-type impurity into the region in which the p-type impurity has been implanted. Thus, the concentration of the p-type impurity is made higher than the concentration of the n-type impurity in every region where the n⁺-type cathode layer 26 is formed.

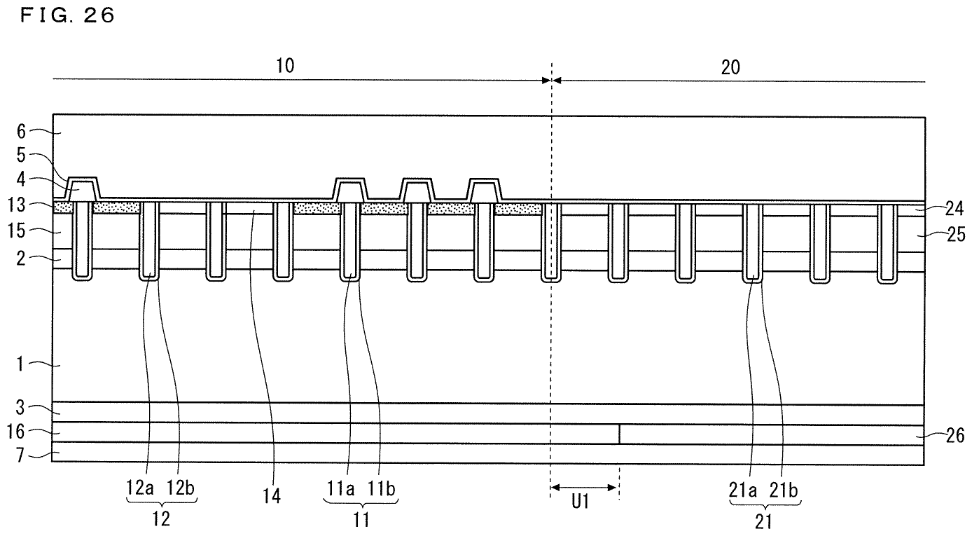

Then, as shown in FIG. 26, the collector electrode 7 is formed on the second main surface of the semiconductor substrate. The collector electrode 7 is formed on the entire second main surface in the IGBT area 10, the diode area 20, and the termination area 30. The collector electrode 7 may also be formed on the entire second main surface of the n-type wafer, i.e., the semiconductor substrate. The collector electrode 7 may be formed depositing, for example, an aluminum-silicon alloy (Ai—Si-based alloy) or titanium (Ti) by PVD such as sputtering or vacuum deposition, or may be formed by stacking a plurality of metals such as an aluminum-silicon alloy, titanium, nickel, or gold one above another. Furthermore, another metal film may be further formed by electroplating or electroless plating on the metal film formed by PVD so as to form the collector electrode 7.

Through the steps describe above, the semiconductor device 100 or 101 is produced. Since a plurality of semiconductor devices 100 or 101 are produced in a matrix on a single n-type wafer, the individual semiconductor devices 100 or 101 may be cut out by laser dicing or blade dicing to complete the semiconductor device 100 or 101.

Here, the n⁺-type source layer 13, the p⁺-type contact layer 14, and the p⁺-type anode contact layer 24 are formed before the formation of the trench gates, the n⁺-type source layer 13, the p⁺-type contact layer 14, or the p⁺-type anode contact layer 24 may be formed after the formation of the trench gates. Even if the n⁺-type source layer 13, the p⁺-type contact layer 14, or the p⁺-type anode contact layer 24 is formed after the formation of the trench gates, it is known that the first dislocations 200 are formed by high-dose implantation and annealing. However, it has never been known before that the second dislocations 201 can be arranged in arbitrary positions by controlling the stresses in the n⁻-type drift layer 1.

### EMBODIMENT 1

In Embodiment 1, the second dislocations 201 are applied to an IGBT in the IGBT area, the IGBT being a bipolar device having trenches (bipolar-type semiconductor element). Here, the IGBT that configures an RC-IGBT is shown as an example, but the bipolar device to which the second dislocations 201 are applied may be a discrete IGBT, or may be any other bipolar device. The following description is given regarding advantages effects using, as an example, a semiconductor device including a semiconductor substrate composed primarily of silicon because silicon elongates the lifetime of the semiconductor substrate. However, a semiconductor substrate composed primarily of silicon carbide, gallium nitride, gallium oxide, or diamond may be used in order to achieve similar advantageous effects.

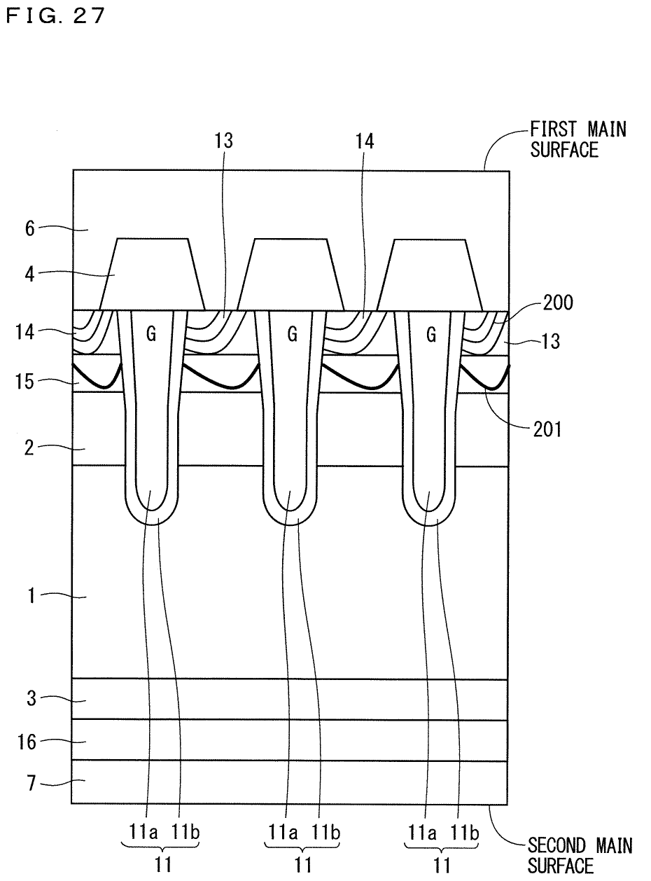

FIGS. 27 to 29 show exemplary configurations of the semiconductor device according to Embodiment 1. FIGS. 27 to 29 show structures of the IGBT area 10 shown in FIGS. 7 and 8 in simplified and integrated form.

FIG. 27 shows an example in which the second dislocations 201 are arranged in the p-type base layer 15 that is located in a position deeper than the n+-type source layer 13 or the p⁺-type contact layer 14 (a position on the second main surface side). The second dislocations 201 may be curved or have a convex shape toward the second main surface, and may include both components with the <110> and <100> orientations of the semiconductor substrate. The presence of the second dislocations 201 arranged in the vicinity of the n—type drift layer 1 locally reduces the carrier lifetime and improves switching losses.

The overall length L1 of the second dislocations 201 is desirably longer than the mesa width W1 in order to improve the effect of reducing the carrier lifetime. As a technique for ensuring the overall length L1 of the second dislocations 201, the dislocations may be curved. In this case, there is no problem even if the second dislocations 201 have the components with the <100> and <110> orientations of the semiconductor substrate. In order to reduce the carrier lifetime on the second main surface side as compared with that in the mesa region, the second dislocations 201 may have a convex shape toward the second main surface.

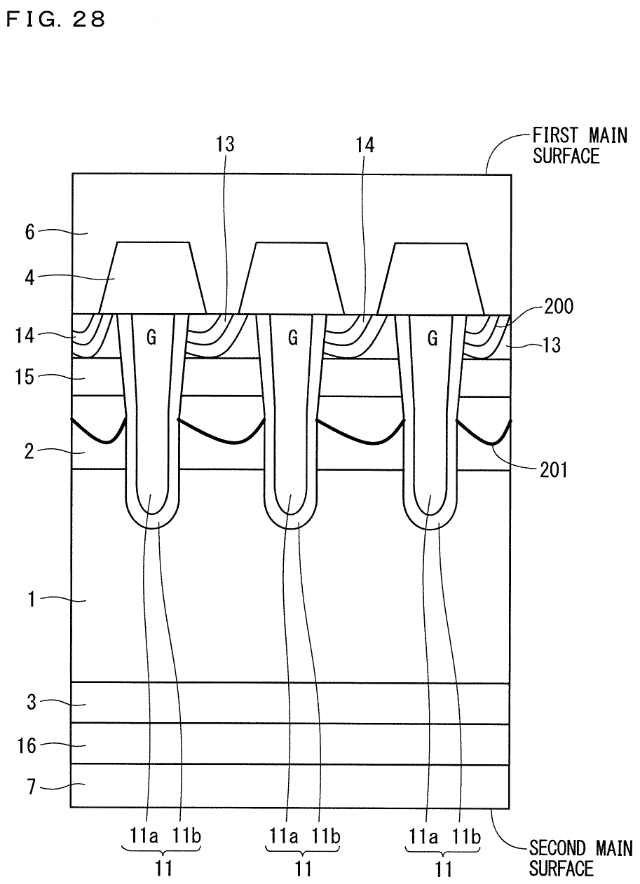

FIG. 28 shows an example in which the second dislocations 201 are arranged within the n-type carrier storage layer 2. That is, the second dislocations 201 are arranged in positions deeper than the p-type base layer 15 or in positions deeper than the interface between the p-type base layer 15 and the n-type carrier storage layer 2.

In the case where the second dislocations 201 are arranged in the p-type base layer 15 as shown in FIG. 27, a threshold voltage for forming a channel will vary because the second dislocations 201 have a bandgap or a Fermi level different from that of perfect crystals. Besides, the channel mobility may degrade because the second dislocations 201 correspond to disturbances in crystallinity. In order to form a reduced carrier lifetime region while avoiding this degradation, it is desirable that the second dislocations 201 are arranged in positions deeper than the p-type base layer 15 as shown in FIG. 28. The “positions deeper than the p-type base layer 15” as used herein refer to positions deeper than a position in which the effective carrier concentration in the depth direction toward the second main surface is inverted from the n type to the p type in the same region as the n+-type source layer 13 in plan view. In other words, the “positions deeper than the p-type base layer 15” refer to the end on the second main surface side of a region where an inversion layer is formed when a voltage higher than the threshold voltage is applied to the gate.

Moreover, since electric field strength at the interface between the p-type base layer 15 and the n-type carrier storage layer 2 increases during turn-off, the presence of the second dislocations 201 in that position increases leak current. Thus, in order to form a reduced carrier lifetime region while suppressing an increase in leakage current, it is desirable that the second dislocations 201 are arranged in positions deeper than the interface between the p-type base layer 15 and the n-type carrier storage layer 2.

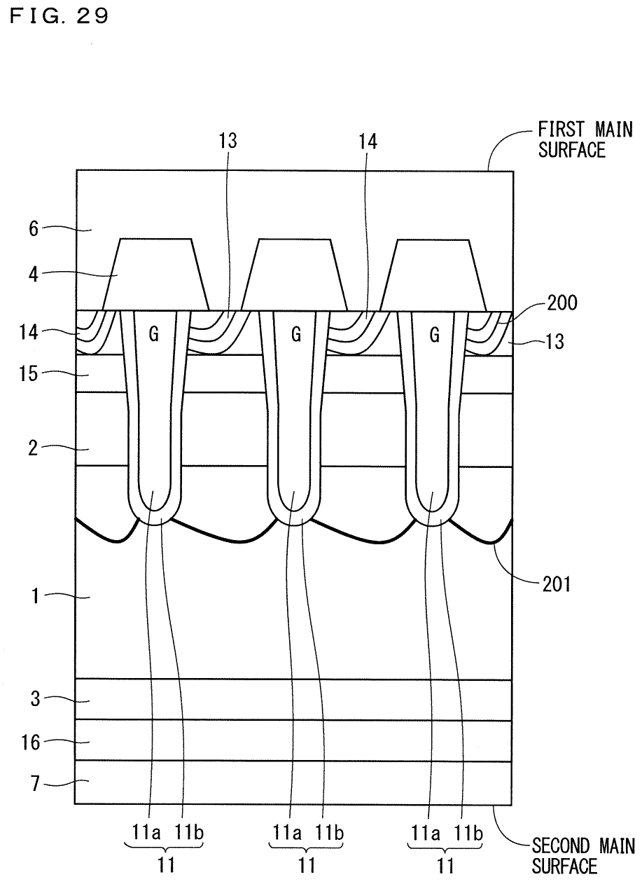

FIG. 29 shows an example in which at least some of the second dislocations 201 are arranged in positions deeper than the bottoms of the active trench gates 11. In the case where the second dislocations 201 are arranged in positions deeper than the active trench gates 11, the reduced carrier lifetime region can be enlarged even in a deep region of the n—type drift layer 1. This increases the effect of reducing switching losses.

### EMBODIMENT 2

In Embodiment 2, the second dislocations 201 are applied to a diode in the diode area 20, the diode being a bipolar device having trenches. Here, the diode that configures an RC-IGBT is described as an example, but the bipolar device to which the second dislocations 201 are applied may be a discrete diode, or may be any other bipolar device.

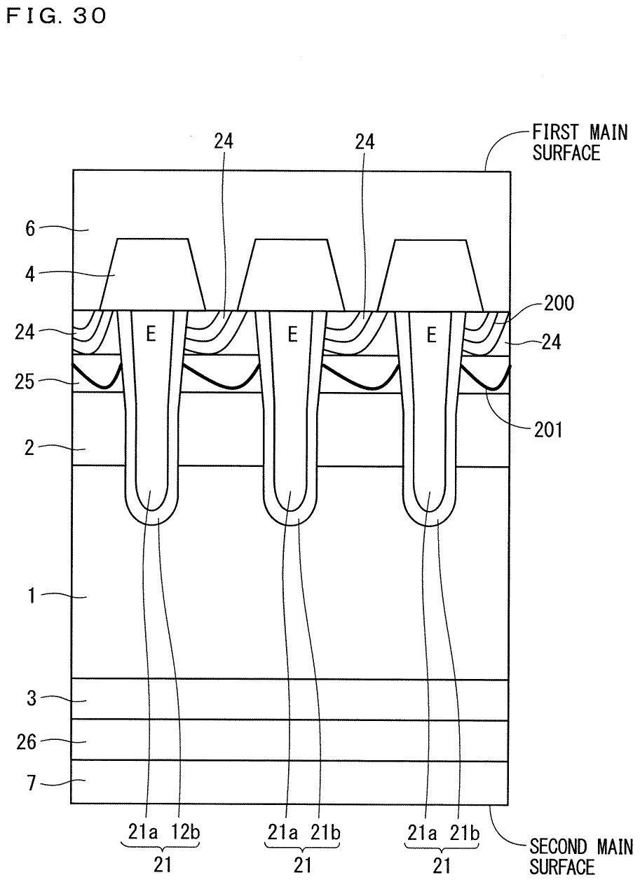

FIGS. 30 to 32 show exemplary configurations of the semiconductor device according to Embodiment 2. FIGS. 30 to 32 show structures of the diode area 20 shown in FIGS. 10 and 11 in simplified and integrated form.

FIG. 30 shows an example in which at least some of the second dislocations 201 are arranged in the p-type anode layer 25 that is located in a position deeper than the p⁺-type anode contact layer 24. The presence of the second dislocations 201 arranged in the diode area 20 reduces recovery losses. By arranging the second dislocations 201 in the region closer to the n⁻-type drift layer 1 or the n-type carrier storage layer 2, it is expected to achieve the effect of reducing the amount of holes supplied during forward operation and the effect of accelerating hole emissions during turn-off. This allows a reduction in recovery losses.

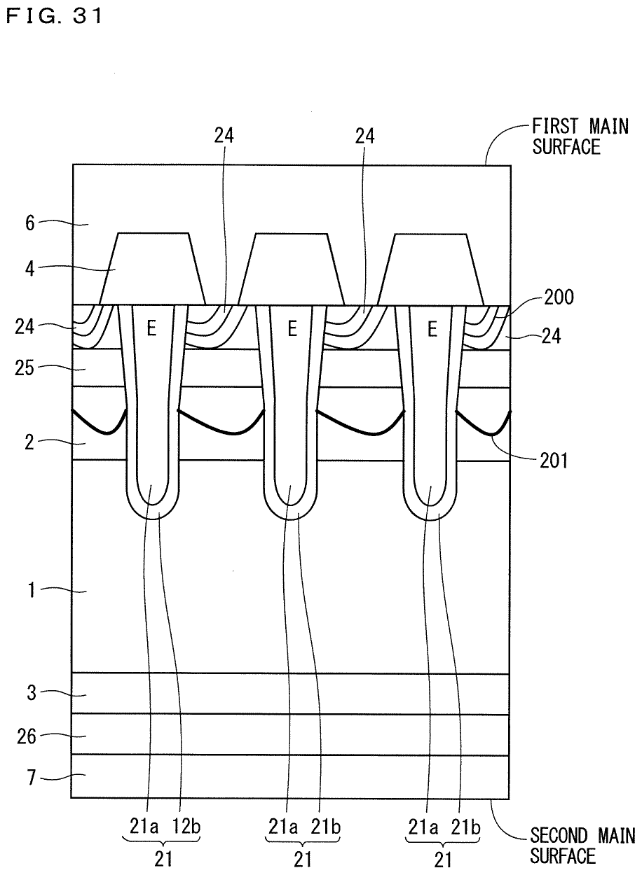

FIG. 31 shows an example in which at least some of the second dislocations 201 are arranged in the n-type carrier storage layer 2. That is, at least some of the second dislocations 201 are arranged in positions deeper than the interface between the p-type anode layer 25 and the n⁻-type drift layer 1. Since electric field strength at the interface between the p-type anode layer 25 and the n—type drift layer 1 increases during turn-off, the presence of the second dislocations 201 arranged in that position increases leakage current. Accordingly, in order to form a reduced carrier lifetime region while avoiding an increase in leakage current, it is desirable that the second dislocations 201 are arranged in positions deeper than the interface between the p-type anode layer 25 and the n—type drift layer 1.

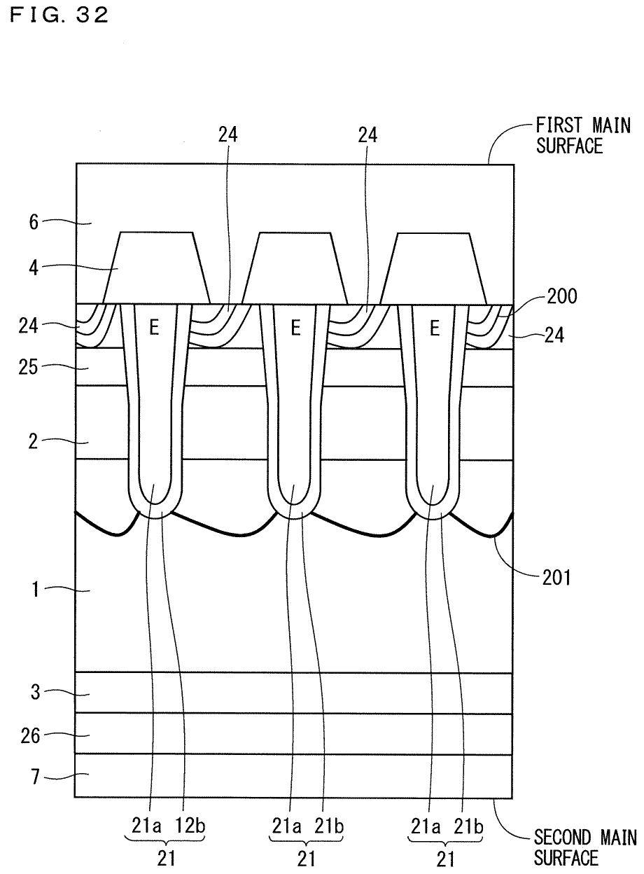

FIG. 32 shows an example in which at least some of the second dislocations 201 are arranged in positions deeper than the diode trench gates 21. By arranging at least some of the second dislocations 201 on the side closer to the second main surface than the diode trench gates 21, it is possible to enlarge the reduced carrier lifetime region even in a region located on the second main surface side of the n⁻-type drift layer 1 and to reduce recovery losses.

### EMBODIMENT 3

While Embodiments 1 and 2 show the examples in which the second dislocations 201 are arranged uniformly in the right-left direction on the plane of the drawing in the IGBT area 10, Embodiment 3 shows an example in which the second dislocations 201 are arranged in part. That is, Embodiment 3 shows an example the arrangement of the second dislocations 201 in plan view.

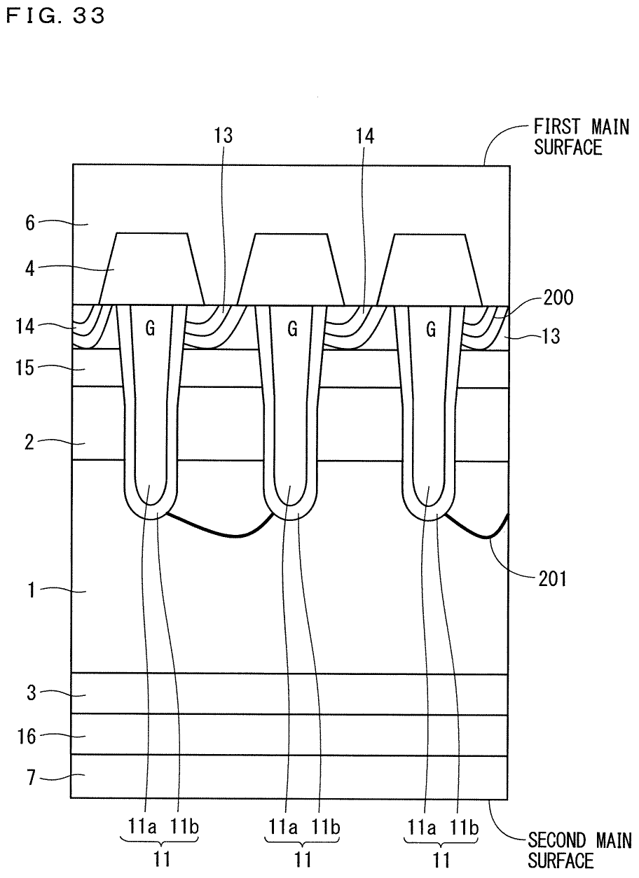

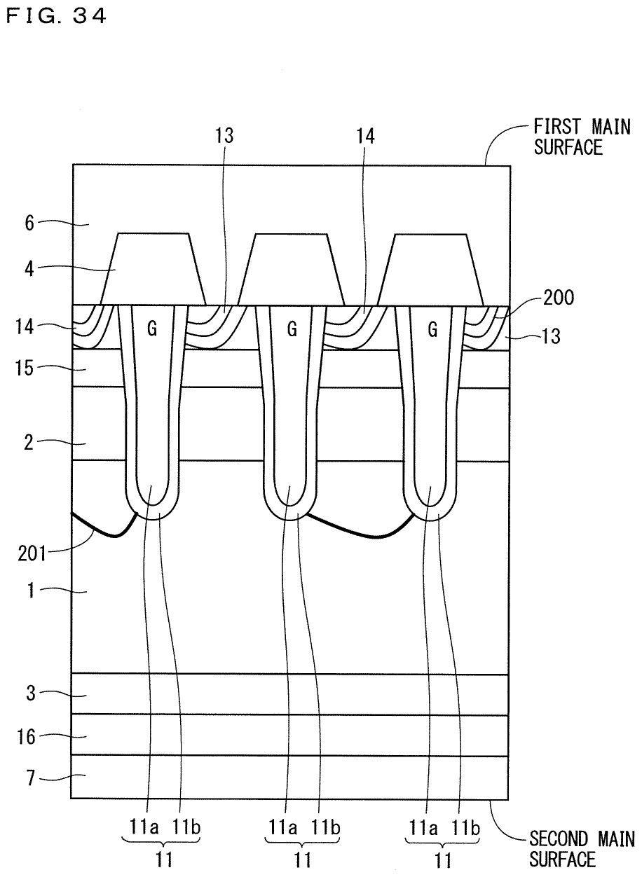

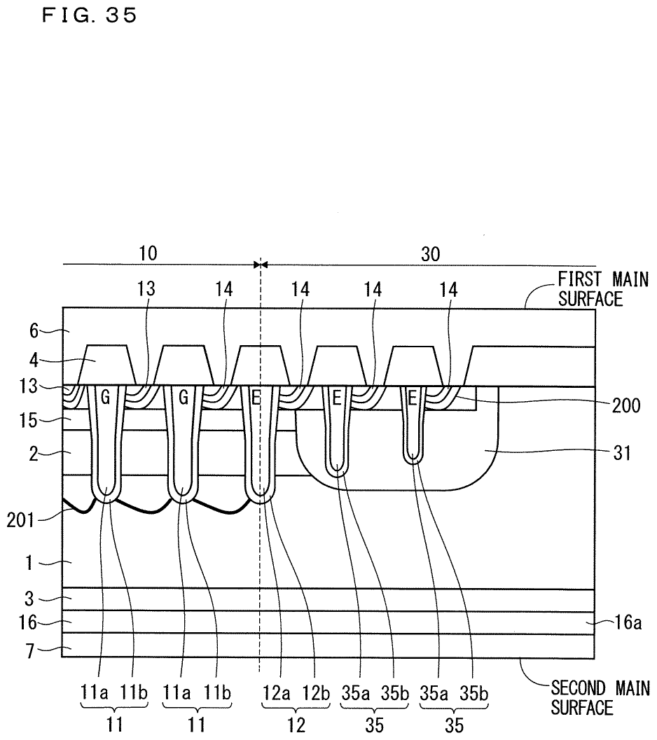

FIGS. 33 to 35 show exemplary configurations of the semiconductor device according to Embodiment 3. FIGS. 33 and 34 show the structures shown in FIG. 7 or 8 in simplified and integrated form, and FIG. 35 shows the structure shown in FIG. 13 in simplified and integrated form.

FIG. 33 shows an example in which the second dislocations 201 are arranged below the n⁺-type source layer 13. That is, the second dislocations 201 are arranged in at least part of the region where the n⁺-type source layer 13 is formed in plan view. The presence of the second dislocations 201 arranged below the n⁺-type source layer 13 accelerates hole emissions immediately under the n⁺-type source layer 13 during turn-off and reduces the occurrence of latch-up. This improves the interrupting capacity of the semiconductor device.

FIG. 34 shows an example in which the second dislocations 201 are arranged below the p⁺-type contact layer 14. That is, the second dislocations 201 are arranged in at least part of the region where the p⁺-type contact layer 14 is formed in plan view. The presence of the second dislocations 201 arranged below the p⁺-type contact layer 14 limits the amount of holes implanted during continuity and reduces the amount of hole emissions, resulting in a reduction in turn-off losses.

FIG. 35 shows an example in which no second dislocations 201 are formed in the termination area 30. That is, the second dislocations 201 are arranged in areas other than the termination area 30. The second dislocations 201 are arranged in the boundary between the IGBT area 10 and the termination area 30.

Since electric field strength in the termination area 30 increases during turn-off, the presence of the second dislocations 201 in the termination area 30 increases leakage current. Besides, a reduction in the carrier lifetime in the termination area 30 has just a small influence on switching losses or the interrupting capacity. Therefore, there is little benefit to arranging the second dislocations 201 in the termination area 30, and there is no need to intentionally arrange the second dislocations 201 in the termination area 30. Accordingly, it is desirable that no second dislocations 201 are formed in the termination area 30.

In FIG. 35, the termination area 30 includes a plurality of terminal dummy trench gates 35. The depths of the terminal dummy trench gates 35 become gradually shallower in a direction toward the outside (in a direction from the cell area toward the termination area). That is, the more outer the terminal dummy trench gates 35 are located, the shallower the terminal dummy trench gates 35 are. In this case, it is more desirable that no second dislocations 201 are formed in the termination area 30 because the terminal dummy trench gates 35 are often designed to have higher electric field strength on the second main surface side.

Meanwhile, it is desirable that the second dislocations 201 are arranged in the boundary between the IGBT area 10 and the termination area 30. This accelerates hole emissions during turn-off and to improve the interrupting capacity of the semiconductor device without changing the amount of hole injection during continuity.

### EMBODIMENT 4

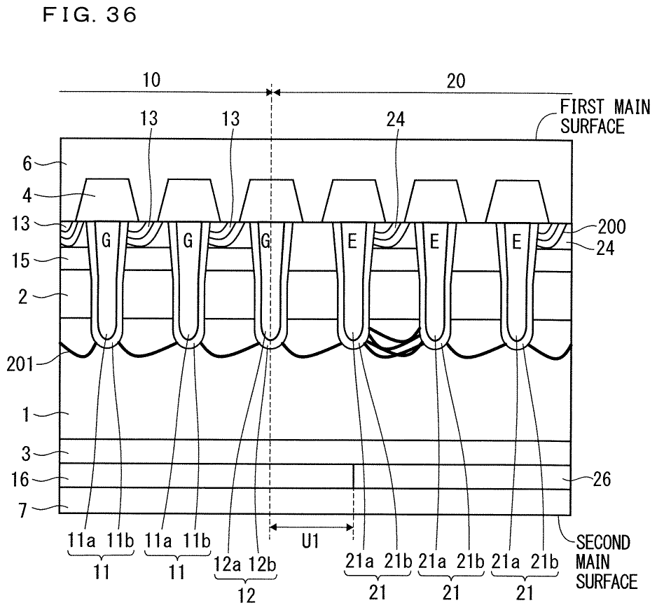

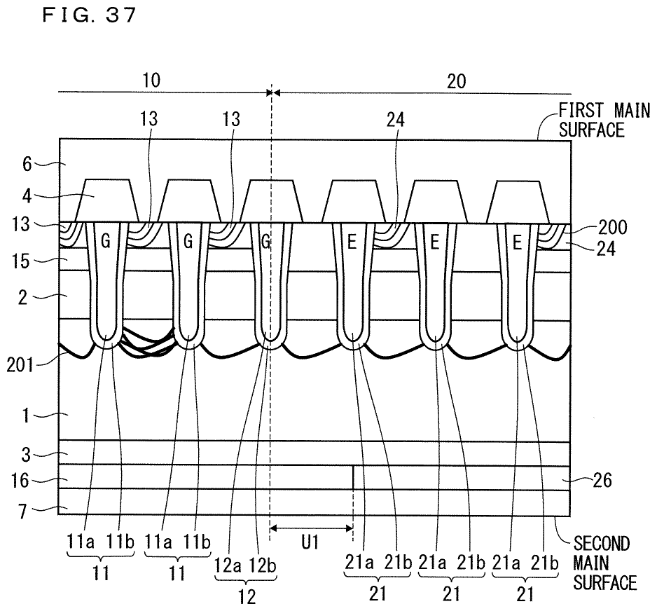

FIGS. 36 and 37 show exemplary configurations of a semiconductor device according to Embodiment 4. FIGS. 36 and 37 show the structure shown in FIG. 12 in simplified and integrated form.

FIG. 36 shows an example in which at least some of the second dislocations 201 are arranged in the boundary area between the IGBT area 10 and the diode area 20. Moreover, at least part of the diode area 20 includes a region in which the second dislocations 201 have a higher density than in the IGBT area 10. In the diode area 20 in plan view, the second dislocations 201 have a higher density in the region where the p⁺-type anode contact layer 24 is formed than in the region where no p⁺-type anode contact layer 24 is formed.

During turn-off of the diode, some of the holes reach the IGBT area 10 and are emitted through the p⁺-type contact layer 14. This may cause the accumulation of holes in the vicinity of the n⁺-type source layer 13, resulting the occurrence of latch-up. If the second dislocations 201 are arranged in the boundary area between the IGBT area 10 and the diode area 20 as shown in FIG. 36, it is possible to increase the interrupting capacity. In the case where there is a desire to actively improve recovery losses in the diode or the interrupting capacity of the diode, the second dislocations 201 may be arranged at a higher density in the diode area 20 than in the IGBT area 10.

The diode area 20 includes the region where the p⁺-type anode contact layer 24 is formed and the region where no p⁺-type anode contact layer 24 is formed. In order to reduce the amount of holes supplied from the p⁺-type anode contact layer 24, it is desirable that the second dislocations 201 are arranged at a higher density in a region that overlaps the p⁺-type anode contact layer 24 in plan view than in a region that does not overlap the p⁺-type anode contact layer 24 in plan view. A reduced amount of holes supplied from the p⁺-type anode contact layer 24 reduces recovery losses. Here, the density of the second dislocations 201 does not need to refer to the density in the entire of each region. Practically, it is assumed that the density of the second dislocations 201 is compared within regions that can be observed in sections used in TEM analysis.

FIG. 37 shows an example in which at least part of the diode area 20 includes a region where the second dislocation 201 has a lower density than in the IGBT area 10. In the case where there is a desire to actively improve turn-off losses in the IGBT or the interrupting capacity of the IGBT, the second dislocations 201 may be arranged at a higher density in the IGBT area 10 than in the diode area 20. Here, the density of the second dislocations 201 does not need to refer to the density in the entire of each region. Practically, it is assumed that the density of the second dislocations 201 is compared within regions that can be observed in sections used in TEM analysis.

### EMBODIMENT 5

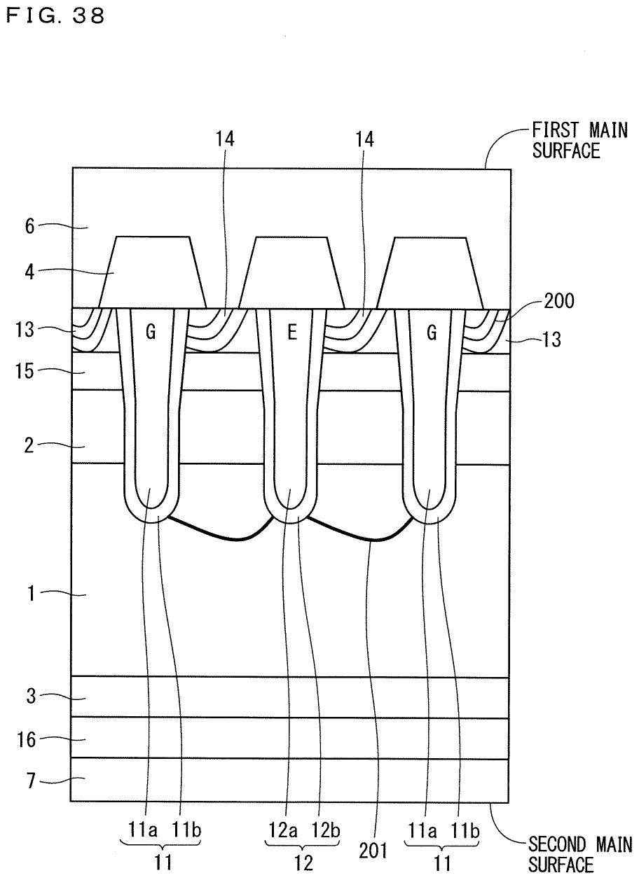

FIG. 38 shows an exemplary configuration of a semiconductor device according to Embodiment 5. FIG. 38 shows the structure shown in FIGS. 7 and 8 in simplified and integrated form.

FIG. 38 shows an example in which active trench gates 11 and a dummy trench gate 12 are arranged in the IGBT area 10. At least some of the second dislocations 201 are arranged in contact with the dummy trench gate 12.

Making effective use of the dummy trench gate 12 reduces the demerits of the arrangement of the second dislocations 201. The second dislocations 201 that reduce the carrier lifetime have the effects of increasing the rate of hole emissions and thereby improving the interrupting capacity and reducing switching losses, but on the other hand, have the demerits of reducing the amount of holes during turn-on and increasing the ON-state voltage. In the case where the second dislocations 201 are arranged around the dummy trench gate 12 as shown in FIG. 38, no channel is formed on the side surface of the dummy trench gate 12 and accordingly no current flow through that portion. Thus, the ON-state voltage does not increase even if the carrier lifetime is reduced. Besides, the effect of trapping holes during turn-off is expected. This improves a trade-off between the ON-state voltage and switching losses.

If the second dislocations 201 are in contact with the active trench gates 11 having a gate potential, electric field strength increases at the point of contact with the gate trench insulation films 11b in the contact portion. This may deteriorate the reliability of the gates. Accordingly, the second dislocations 201 are preferably in contact with the dummy trench gate 12, instead of the active trench gates 11. The term “contact” as used herein refers to a substantial connection in the technique of analysis such as TEM.

### EMBODIMENT 6

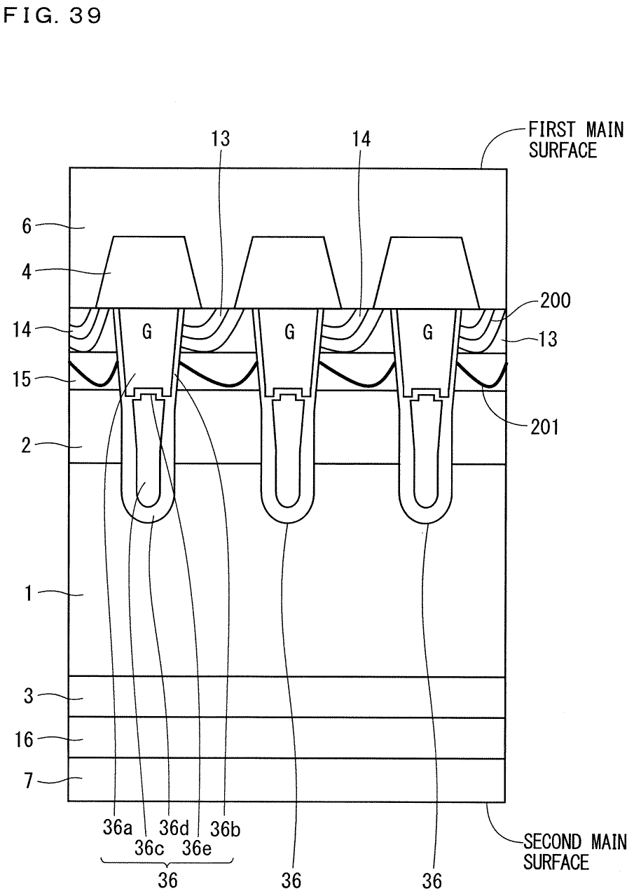

FIGS. 39 to 41 show exemplary configurations of a semiconductor device according to Embodiment 6. FIGS. 39 to 41 show the structure shown in FIGS. 7 and 8 in simplified and integrated form. It is, however, noted that double trench gates 36 having a double gate structure are provided, instead of the active trench gates 11.

The configuration shown in FIG. 49 differs from the configuration according to Embodiment 1 (FIG. 27) in that the double trench gates 36 are arranged, instead of the active trench gates 11. Each double trench gate 36 is configured by embedding a lower gate trench electrode 36c via a lower gate trench insulation film 36d in a lower portion of a trench formed in the semiconductor substrate (a portion on the second main surface side) and embedding an upper gate trench electrode 36a via an upper gate trench insulation film 36b in an upper portion of the trench (a portion on the first main surface side). The upper gate trench insulation film 36b and the upper gate trench electrode 36a are isolated from each other by an intermediate insulation film 36e, so that the upper gate trench electrode 36a and the upper gate trench insulation film 36b can be set to have different potentials. In the present embodiment, the upper gate trench electrode 36a is set to a gate potential, and the lower gate trench electrode 36c is set to an emitter potential. That is, the lower gate trench electrode 36c is electrically connected to the emitter electrode 6.

The use of the double trench gates 36 having a double gate structure increases the stresses in the n⁻-type drift layer 1 and facilitates the arrangement of the second dislocations 201 in the n⁻-type drift layer 1 as compared with the case of using the active trench gates 11 having a single gate structure.

In the configuration according to Embodiment 1 (FIG. 27), if the stresses in the n-type drift layer 1 are controlled by changing the thickness of the gate trench insulation films 11b of the active trench gates 11, important electrical characteristics such as the threshold voltage will vary. In contrast, in the configuration according to Embodiment 6 (FIG. 39), even if the stresses in the n⁻-type drift layer 1 are controlled by changing the thickness of the lower gate trench insulation films 36d of the double trench gates 36 important electrical characteristics such as the threshold voltage will not vary as long as the lower gate trench electrodes 36c are set to the emitter potential. Therefore, according to the present embodiment, the thickness of the lower gate trench insulation films 36d can be designed as an independent parameter for stress control.

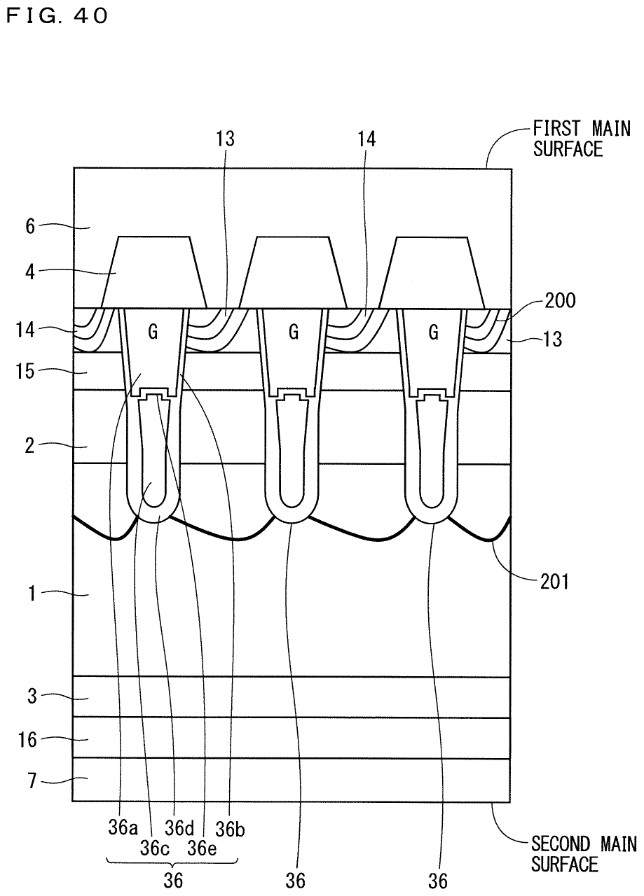

FIG. 40 shows an example in which the second dislocations 201 are arranged in contact with the lower gate trench insulation films 36d. The lower gate trench insulation films 36d are thicker than the upper gate trench insulation films 36b. Besides, no second dislocations 201 are arranged in the boundary portions between the upper gate trench insulation films 36b and the lower gate trench insulation films 36d (the boundary portions between the upper gate trench electrodes 36a and the lower gate trench electrodes 36c).

In the case where the second dislocations 201 are in contact with the upper gate trench insulation films 36b that performs potential control in order to form a channel, electric field strength at the point of contact may locally increase and deteriorate the reliability of the gates. Therefore, it is desirable that the second dislocations 201 are in contact with the lower gate trench insulation films 36d. Besides, the stresses in the n—type drift layer 1 can be increased by increasing the thickness of the lower gate trench insulation films 36d.

In the case where the lower gate trench electrodes 36c are not set to the emitter potential, deterioration in the reliability of the gates can be suppressed by bringing the second dislocations 201 into contact with the lower gate trench insulation films 36d that are designed to have a great thickness. In the case where the second dislocations 201 are arranged in the boundary portions between the upper gate trench insulation films 36b and the lower gate trench insulation films 36d, mechanical vulnerability may increase in the boundary portions and deteriorate reliability such as breakdown caused by the application of external stress.

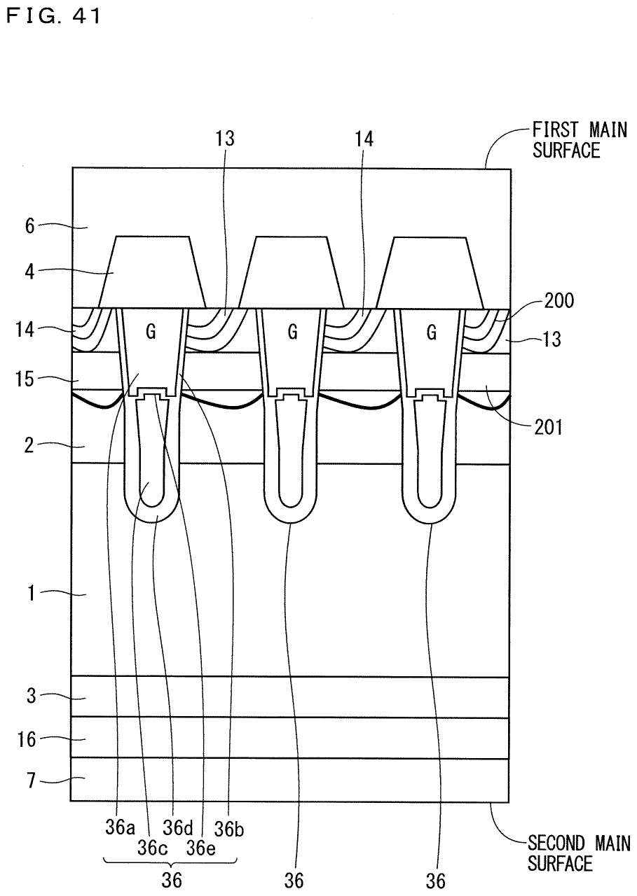

FIG. 41 shows an example in which at least some of the second dislocations 201 are in contact with the boundary portions between the upper gate trench insulation films 36b and the lower gate trench insulation films 36d. The boundary portions between the upper gate trench insulation films 36b and the lower gate trench insulation films 36d are regions that are high in stress and thermally unstable. Thus, when an external stress is applied that causes a shift of dislocations, the second dislocations 201 are likely to shift into the boundary portions between the upper gate trench insulation films 36b and the lower gate trench insulation films 36d. The shift of the second dislocations 201 may cause electrical characteristics to fluctuate. Thus, the second dislocations 201 are arranged in advance in the boundary portions between the upper gate trench insulation films 36b and the lower gate trench insulation films 36d. This reduces the possibility that electrical characteristics may vary when a stress is applied in, for example, a heat cyclic test.

It should be noted that the present disclosure can be implemented by freely combining each embodiment or making appropriate modifications or omissions on each embodiment without departing from the scope of the present disclosure.

### Appendixes

Various modes of the present disclosure are described in summary as appendices given below.

### Appendix 1

A semiconductor device includes a bipolar-type semiconductor element that includes a semiconductor substrate having a first main surface and a second main surface and having a drift layer of a first conductivity type formed therein, a plurality of trenches formed in the first main surface of the semiconductor substrate, an electrode embedded in each of the plurality of trenches via an insulation film, a mesa region that is a region located between the plurality of trenches in the semiconductor substrate, and a source layer of the first conductivity type or a contact layer of a second conductivity type formed in a surface layer of the mesa region on a side closer to the first main surface. The mesa region includes dislocations in positions located on a side closer to the second main surface than the source layer or the contact layer, the dislocations having an overall length greater than a width of the mesa region.

### Appendix 2

In the semiconductor device according to Appendix 1, the dislocations have a curved shape.

### Appendix 3

In the semiconductor device according to Appendix 2, the dislocations are curved in a convex shape toward the second main surface.

### Appendix 4

In the semiconductor device according to any one of Appendixes 1 to 3, the dislocations have a component with a <110> orientation of the semiconductor substrate and a component with a <100> orientation of the semiconductor substrate.

### Appendix 5

In the semiconductor device according to any one of Appendixes 1 to 4, the semiconductor substrate is composed primarily of silicon.

### Appendix 6

In the semiconductor device according to any one of Appendixes 1 to 5, the bipolar-type semiconductor element is an insulated gate bipolar transistor (IGBT) or a reverse conducting IGBT (RC-IGBT) that includes an IGBT and a diode.

### Appendix 7

In the semiconductor device according to Appendix 6, the source layer or the contact layer is arranged in a surface layer of a base layer of the second conductivity type that is formed in the surface layer of the mesa region on the side closer to the first main surface, and the dislocations are arranged on a side closer to the second main surface than the base layer.

### Appendix 8

The semiconductor device according to Appendix 7 further includes a carrier storage layer formed on a side of the base layer that is closer to the second main surface. The dislocations are arranged on a side closer to the second main surface than an interface between the base layer and the carrier storage layer.

### Appendix 9

In the semiconductor device according to Appendix 6, at least some of the dislocations are located on a side closer to the second main surface than bottoms of the plurality of trenches.

### Appendix 10

In the semiconductor device according to Appendix 6, the dislocations overlap at least part of the source layer in plan view.

### Appendix 11

In the semiconductor device according to Appendix 6, the dislocations overlap at least part of the contact layer in plan view.

### Appendix 12

The semiconductor device according to Appendix 6 further includes a termination area provided around an IGBT area in which the IGBT is arranged. The dislocations are not provided in the termination area.

### Appendix 13

In the semiconductor device according to Appendix 12, the termination area includes a plurality of terminal dummy trench gates, and the more outer the plurality of terminal dummy trench gates are located, the shallower the plurality of terminal dummy trench gates are.

### Appendix 14

The semiconductor device according to Appendix 6 further includes a termination area provided around an IGBT area in which the IGBT is arranged. At least some of the dislocations are arranged in a boundary area between the IGBT area and the termination area.

### Appendix 15

In the semiconductor device according to Appendix 6, some of the electrodes embedded in the plurality of trenches serve as a dummy trench electrode that is electrically connected to an emitter electrode.

### Appendix 16

In the semiconductor device according to Appendix 15, at least some of the dislocations are in contact with a trench having the dummy trench electrode embedded therein.

### Appendix 17

In the semiconductor device according to Appendix 6, the electrodes embedded in the plurality of trenches are each separated into an upper gate trench electrode located on a side closer to the first main surface and a lower gate trench electrode located on a side closer to the second main surface, and the upper gate trench electrode and the lower gate trench electrode are isolated from each other by an intermediate insulation film.

### Appendix 18

In the semiconductor device according to Appendix 17, the insulation film in each of the plurality of trenches includes an upper gate trench insulation film and a lower gate trench insulation film, the upper gate trench insulation film being located on a side closer to the first main surface than the intermediate insulation film, the lower gate trench insulation film being located on a side closer to the second main surface than the intermediate insulation film, and at least some of the dislocations are in contact with the lower gate trench insulation film.

### Appendix 19

In the semiconductor device according to Appendix 17, the insulation film in each of the plurality of trenches includes an upper gate trench insulation film and a lower gate trench insulation film, the upper gate trench insulation film being located on a side closer to the first main surface than the intermediate insulation film, the lower gate trench insulation film being located on a side closer to the second main surface than the intermediate insulation film, and the lower gate trench insulation film has a greater thickness than the upper gate trench insulation film.

### Appendix 20

In the semiconductor device according to Appendix 19, at least some of the dislocations are in contact with the lower gate trench insulation film.

### Appendix 21

In the semiconductor device according to Appendix 17, the insulation film in each of the plurality of trenches includes an upper gate trench insulation film and a lower gate trench insulation film, the upper gate trench insulation film being located on a side closer to the first main surface than the intermediate insulation film, the lower gate trench insulation film being located on a side closer to the second main surface than the intermediate insulation film, and the dislocations are not in contact with a boundary portion between the upper gate trench insulation film and the lower gate trench insulation film.

### Appendix 22

In the semiconductor device according to Appendix 17, the insulation film in each of the plurality of trenches includes an upper gate trench insulation film and a lower gate trench insulation film, the upper gate trench insulation film being located on a side closer to the first main surface than the intermediate insulation film, the lower gate trench insulation film being located on a side closer to the second main surface than the intermediate insulation film, and at least some of the dislocations are in contact with a boundary portion between the upper gate trench insulation film and the lower gate trench insulation film.

### Appendix 23

In the semiconductor device according to any one of Appendixes 1 to 5, the bipolar-type semiconductor element is a diode or a RC-IGBT that includes a diode and an IGBT.

### Appendix 24

In the semiconductor device according to Appendix 23, the contact layer is arranged in a surface layer of an anode layer of the second conductivity type that is formed in the surface layer of the mesa region on the side closer to the first main surface, and at least some of the dislocations are arranged in the anode layer.

### Appendix 25

In the semiconductor device according to Appendix 23, the contact layer is arranged in a surface layer of an anode layer of the second conductivity type that is formed in the surface layer of the mesa region on the side closer to the first main surface, and at least some of the dislocations are arranged on a side closer to the second main surface than an interface between the anode layer and the drift layer.

### Appendix 26

In the semiconductor device according to Appendix 23, at least some of the dislocations are located on a side closer to the second main surface than bottoms of the plurality of trenches.

### Appendix 27

In the semiconductor device according to Appendix 23, the bipolar-type semiconductor element is the RC-IGBT, and at least some of the dislocations are arranged in a boundary between an IGBT area in which the IGBT is arranged and a diode area in which the diode is arranged.

### Appendix 28

In the semiconductor device according to Appendix 23, the bipolar-type semiconductor element is the RC-IGBT, the dislocations are arranged in both an IGBT area in which the IGBT is arranged and a diode area in which the diode is arranged, and at least part of the IGBT area includes a region where the dislocations have a higher density than in the diode area.

### Appendix 29

In the semiconductor device according to Appendix 23, the bipolar-type semiconductor element is the RC-IGBT, the dislocations are arranged in both an IGBT area in which the IGBT is arranged and a diode area in which the diode is arranged, and at least part of the diode area includes a region where the dislocations have a higher density than in the IGBT area.

### Appendix 30

In the semiconductor device according to Appendix 23, the dislocations have a higher density in a region that overlaps the contact layer in plan view than in a region that does not overlap the contact layer in plan view.

### Appendix 31

A method of manufacturing a semiconductor device includes preparing a semiconductor substrate having a first main surface and a second main surface and having a drift layer of a first conductivity type formed therein, forming a source layer of a first conductivity type or a contact layer of a second conductivity type in a surface layer of the semiconductor substrate on a side closer to the first main surface, the source layer or the contact layer including a first dislocation, and forming a second dislocation in a position located on a side closer to the second main surface than the source layer or the contact layer by subjecting the first dislocation to heat treatment to shift the first dislocation to a position located on a side closer to the second main surface than the source layer or the contact layer.

### Appendix 32

The method of manufacturing a semiconductor device according to Appendix 31 further includes forming a plurality of trenches in the first main surface of the semiconductor substrate, the plurality of trenches reaching the drift layer, and embedding an electrode in each of the plurality of trenches via an insulation film. In the formation of the second dislocation, the second dislocation is formed to have an overall length greater than a width of a mesa region that is a region located between the plurality of trenches of the semiconductor substrate.

While the disclosure has been shown and described in detail, the foregoing description is in all aspects illustrative and not restrictive. It is therefore understood that numerous modifications and variations can be devised.

What is claimed is:

1. A semiconductor device comprising:
a bipolar-type semiconductor element including:
a semiconductor substrate having a first main surface and a second main surface and having a drift layer of a first conductivity type formed therein;
a plurality of trenches formed in the first main surface of the semiconductor substrate;
an electrode embedded in each of the plurality of trenches via an insulation film;
a mesa region that is a region located between the plurality of trenches in the semiconductor substrate; and
a source layer of the first conductivity type or a contact layer of a second conductivity type formed in a surface layer of the mesa region on a side closer to the first main surface,
wherein the mesa region includes dislocations in positions located on a side closer to the second main surface than the source layer or the contact layer, the dislocations having an overall length greater than a width of the mesa region.

2. The semiconductor device according to claim 1, wherein the dislocations have a curved shape.

3. The semiconductor device according to claim 2, wherein the dislocations are curved in a convex shape toward the second main surface.

4. The semiconductor device according to claim 1, wherein
the dislocations have a component with a <110> orientation of the semiconductor substrate and a component with a <100> orientation of the semiconductor substrate.

5. The semiconductor device according to claim 1, wherein the semiconductor substrate is composed primarily of silicon.

6. The semiconductor device according to claim 1, wherein
the bipolar-type semiconductor element is an insulated gate bipolar transistor (IGBT) or a reverse conducting IGBT (RC-IGBT) that includes an IGBT and a diode.

7. The semiconductor device according to claim 6, wherein
the source layer or the contact layer is arranged in a surface layer of a base layer of the second conductivity type that is formed in the surface layer of the mesa region on the side closer to the first main surface, and
the dislocations are arranged on a side closer to the second main surface than the base layer.

8. The semiconductor device according to claim 7, further comprising:
a carrier storage layer formed on a side of the base layer that is closer to the second main surface,
wherein the dislocations are arranged on a side closer to the second main surface than an interface between the base layer and the carrier storage layer.

9. The semiconductor device according to claim 6, wherein
at least some of the dislocations are located on a side closer to the second main surface than bottoms of the plurality of trenches.

10. The semiconductor device according to claim 6, wherein
the dislocations overlap at least part of the source layer in plan view.

11. The semiconductor device according to claim 6, wherein
the dislocations overlap at least part of the contact layer in plan view.

12. The semiconductor device according to claim 6, further comprising:
a termination area provided around an IGBT area in which the IGBT is arranged,
wherein the dislocations are not provided in the termination area.

13. The semiconductor device according to claim 12, wherein
the termination area includes a plurality of terminal dummy trench gates, and
the more outer the plurality of terminal dummy trench gates are located, the shallower the plurality of terminal dummy trench gates are.

14. The semiconductor device according to claim 6, further comprising:
a termination area provided around an IGBT area in which the IGBT is arranged,
wherein at least some of the dislocations are arranged in a boundary area between the IGBT area and the termination area.

15. The semiconductor device according to claim 6, wherein
some of the electrodes embedded in the plurality of trenches serve as a dummy trench electrode that is electrically connected to an emitter electrode.

16. The semiconductor device according to claim 15, wherein
at least some of the dislocations are in contact with a trench having the dummy trench electrode embedded therein.

17. The semiconductor device according to claim 6, wherein
the electrodes embedded in the plurality of trenches are each separated into an upper gate trench electrode located on a side closer to the first main surface and a lower gate trench electrode located on a side closer to the second main surface, and
the upper gate trench electrode and the lower gate trench electrode are isolated from each other by an intermediate insulation film.

18. The semiconductor device according to claim 17, wherein
the insulation film in each of the plurality of trenches includes an upper gate trench insulation film and a lower gate trench insulation film, the upper gate trench insulation film being located on a side closer to the first main surface than the intermediate insulation film, the lower gate trench insulation film being located on a side closer to the second main surface than the intermediate insulation film, and
at least some of the dislocations are in contact with the lower gate trench insulation film.

19. The semiconductor device according to claim 17, wherein
the insulation film in each of the plurality of trenches includes an upper gate trench insulation film and a lower gate trench insulation film, the upper gate trench insulation film being located on a side closer to the first main surface than the intermediate insulation film, the lower gate trench insulation film being located on a side closer to the second main surface than the intermediate insulation film, and
the lower gate trench insulation film has a greater thickness than the upper gate trench insulation film.

20. The semiconductor device according to claim 19, wherein
at least some of the dislocations are in contact with the lower gate trench insulation film.

21. The semiconductor device according to claim 17, wherein
the insulation film in each of the plurality of trenches includes an upper gate trench insulation film and a lower gate trench insulation film, the upper gate trench insulation film being located on a side closer to the first main surface than the intermediate insulation film, the lower gate trench insulation film being located on a side closer to the second main surface than the intermediate insulation film, and
the dislocations are not in contact with a boundary portion between the upper gate trench insulation film and the lower gate trench insulation film.

22. The semiconductor device according to claim 17, wherein
the insulation film in each of the plurality of trenches includes an upper gate trench insulation film and a lower gate trench insulation film, the upper gate trench insulation film being located on a side closer to the first main surface than the intermediate insulation film, the lower gate trench insulation film being located on a side closer to the second main surface than the intermediate insulation film, and
at least some of the dislocations are in contact with a boundary portion between the upper gate trench insulation film and the lower gate trench insulation film.

23. The semiconductor device according to claim 1, wherein
the bipolar-type semiconductor element is a diode or a RC-IGBT that includes a diode and an IGBT.

24. The semiconductor device according to claim 23, wherein
the contact layer is arranged in a surface layer of an anode layer of the second conductivity type that is formed in the surface layer of the mesa region on the side closer to the first main surface, and
at least some of the dislocations are arranged in the anode layer.

25. The semiconductor device according to claim 23, wherein
the contact layer is arranged in a surface layer of an anode layer of the second conductivity type that is formed in the surface layer of the mesa region on the side closer to the first main surface, and
at least some of the dislocations are arranged on a side closer to the second main surface than an interface between the anode layer and the drift layer.

26. The semiconductor device according to claim 23, wherein
at least some of the dislocations are located on a side closer to the second main surface than bottoms of the plurality of trenches.

27. The semiconductor device according to claim 23, wherein
the bipolar-type semiconductor element is the RC-IGBT, and
at least some of the dislocations are arranged in a boundary between an IGBT area in which the IGBT is arranged and a diode area in which the diode is arranged.

28. The semiconductor device according to claim 23, wherein
the bipolar-type semiconductor element is the RC-IGBT,
the dislocations are arranged in both an IGBT area in which the IGBT is arranged and a diode area in which the diode is arranged, and
at least part of the IGBT area includes a region where the dislocations have a higher density than in the diode area.

29. The semiconductor device according to claim 23, wherein
the bipolar-type semiconductor element is the RC-IGBT,
the dislocations are arranged in both an IGBT area in which the IGBT is arranged and a diode area in which the diode is arranged, and
at least part of the diode area includes a region where the dislocations have a higher density than in the IGBT area.

30. The semiconductor device according to claim 23, wherein
the dislocations have a higher density in a region that overlaps the contact layer in plan view than in a region that does not overlap the contact layer in plan view.

31. A method of manufacturing a semiconductor device, comprising:
preparing a semiconductor substrate having a first main surface and a second main surface and having a drift layer of a first conductivity type formed therein;
forming a source layer of a first conductivity type or a contact layer of a second conductivity type in a surface layer of the semiconductor substrate on a side closer to the first main surface, the source layer or the contact layer including a first dislocation; and
forming a second dislocation in a position located on a side closer to the second main surface than the source layer or the contact layer by subjecting the first dislocation to heat treatment to shift the first dislocation to a position located on a side closer to the second main surface than the source layer or the contact layer.

32. The method of manufacturing a semiconductor device according to claim 31, further comprising:
forming a plurality of trenches in the first main surface of the semiconductor substrate, the plurality of trenches reaching the drift layer; and
embedding an electrode in each of the plurality of trenches via an insulation film,
wherein in the formation of the second dislocation, the second dislocation is formed to have an overall length greater than a width of a mesa region that is a region located between the plurality of trenches of the semiconductor substrate.
